(19) United States
(12) Patent Application Publication
(10) Pub. No.: US 2026/0215240 A1
(43) Pub. Date: Jul. 23, 2026

(54) METHOD OF FABRICATING A THREE-DIMENSIONAL SEMICONDUCTOR DEVICE

(71) Applicant: SAMSUNG ELECTRONICS CO., LTD., Suwon-si (KR)

(72) Inventors: Jeong-Hee CHOI, Suwon-si (KR); Byeongju KIM, Suwon-si (KR); Sangjun PARK, Suwon-si (KR); Min-Hee LEE, Suwon-si (KR); Bongcheol KIM, Suwon-si (KR)

(73) Assignee: SAMSUNG ELECTRONICS CO., LTD., Suwon-si (KR)

(21) Appl. No.: 19/332,714

(22) Filed: Sep. 18, 2025

(30) Foreign Application Priority Data
Jan. 22, 2025 (KR) 10-2025-0009414

(51) Int. Cl. H01L 21/768; H10B 43/20

(52) U.S. Cl. CPC H10W 20/089; H10B 43/20; H10W 20/076

(57) ABSTRACT

A method of fabricating a three-dimensional semiconductor device includes forming a mold structure on a substrate, forming a first mask pattern on the mold structure, the first mask pattern having a first opening, forming a first spacer insulating layer on the first mask pattern, and forming a second mask pattern on the first spacer insulating layer, the second mask pattern having a second opening overlapping the first opening.

### CROSS-REFERENCE TO RELATED APPLICATIONS

This U.S. non-provisional patent application is based on and claims priority under 35 U.S.C. § 119 to Korean Patent Application No. 10-2025-0009414, filed on Jan. 22, 2025, in the Korean Intellectual Property Office, the entire contents of which are hereby incorporated by reference.

### BACKGROUND

The disclosure relates to a method of fabricating a three-dimensional semiconductor device, and in particular, to a method of fabricating a three-dimensional semiconductor, in which electrode contacts penetrating a stack are provided.

A semiconductor device capable of storing a large amount of data is required as a data storage of an electronic system. Higher integration of semiconductor devices is required to satisfy consumer demands for large data storing capacity, superior performance, and inexpensive prices. In the case of two-dimensional or planar semiconductor devices, since their integration is mainly determined by the area occupied by a unit memory cell, integration is greatly influenced by the level of a fine pattern forming technology. However, very expensive process equipment needed to increase pattern fineness sets a practical limitation on increasing integration for two-dimensional or planar semiconductor devices. Thus, three-dimensional semiconductor devices including three-dimensionally arranged memory cells have recently been proposed.

### SUMMARY

Embodiments of the disclosure provide a method of improving a process of fabricating a three-dimensional semiconductor device.

Embodiments of the disclosure provide a method of fabricating a three-dimensional semiconductor device with improved electrical and reliability characteristics.

According to an aspect of the disclosure, there is provided a method of fabricating a three-dimensional semiconductor device, including: forming a mold structure on a substrate, forming a first mask pattern on the mold structure, the first mask pattern having a first opening, forming a first spacer insulating layer on the first mask pattern, and forming a second mask pattern on the first spacer insulating layer, the second mask pattern having a second opening overlapping the first opening.

According to another aspect of the disclosure, there is provided a method of fabricating a three-dimensional semiconductor device, including: forming a mold structure on a substrate, the substrate including a cell array region and a connection region, forming a first mask pattern on the mold structure, the first mask pattern having a first opening, forming a spacer insulating layer on the first mask pattern, forming a second mask pattern on the spacer insulating layer, the second mask pattern having a second opening, and forming a contact hole extended into the mold structure, wherein the spacer insulating layer is provided on an inner side surface of the first opening.

According to another aspect of the disclosure, there is provided a method of fabricating a three-dimensional semiconductor device, including: forming a mold structure including a plurality of interlayer insulating layers and a plurality of sacrificial layers that are alternatingly stacked on a substrate, the substrate including a cell array region and a connection region, forming a plurality of vertical structures on the cell array region to penetrate the mold structure, forming a first mask pattern on the mold structure the first mask pattern having a first opening, forming a spacer insulating layer on the first mask pattern, forming a second mask pattern on the spacer insulating layer, the second mask pattern having a second opening, performing an etching process using the first mask pattern and second mask pattern to form a contact hole extended into the mold structure, forming an electrode contact in the contact hole; and removing the plurality of sacrificial layers of the mold structure to form a plurality of gate electrodes, wherein the first opening overlaps the second opening on the connection region.

### BRIEF DESCRIPTION OF DRAWINGS

The above and/or other aspects, features, and advantages of the present disclosure will become apparent and more readily appreciated from the following description of example embodiments, taken in conjunction with the accompanying drawings in which:

FIG. 1 is a diagram schematically illustrating an electronic system including a three-dimensional semiconductor device according to an embodiment of the disclosure.

FIG. 2 is a perspective view schematically illustrating an electronic system including a three-dimensional semiconductor device according to an embodiment of the disclosure.

FIGS. 3 and 4 are sectional views, which are taken along a line I-I′ of FIG. 2 to illustrate a semiconductor package including a three-dimensional semiconductor device according to an embodiment of the disclosure.

FIG. 5 is a plan view illustrating a three-dimensional semiconductor device according to an embodiment of the disclosure.

FIGS. 6A and 6B are sectional views, which are taken along lines A-A′ and B-B′ of FIG. 5 to illustrate a three-dimensional semiconductor device according to an embodiment of the disclosure.

FIG. 7 is an enlarged view illustrating a portion (e.g., X of FIG. 6B) of a three-dimensional semiconductor device according to an embodiment of the disclosure.

FIGS. 8A, 8B, 9A, 9B, 10A, 10B, 11A, 11B, 12A, 12B, 13A, 13B, 14A, 14B, 15A, 15B, 16A and 16B are diagrams illustrating a method of fabricating a three-dimensional semiconductor device, according to an embodiment of the disclosure.

FIGS. 17A, 17B, 18A and 18B are diagrams illustrating a method of fabricating a three-dimensional semiconductor device, according to an embodiment of the disclosure.

FIG. 19 is a plan view illustrating a three-dimensional semiconductor device according to an embodiment of the disclosure.

FIGS. 20A and 20B are sectional views, which are taken alone lines C-C′ and D-D′ of FIG. 19 to illustrate a three-dimensional semiconductor device according to an embodiment of the disclosure.

### DETAILED DESCRIPTION

Example embodiments of the disclosures will now be described more fully with reference to the accompanying drawings, in which example embodiments are shown. Like reference numerals in the drawings denote like elements, and thus their description will be omitted.

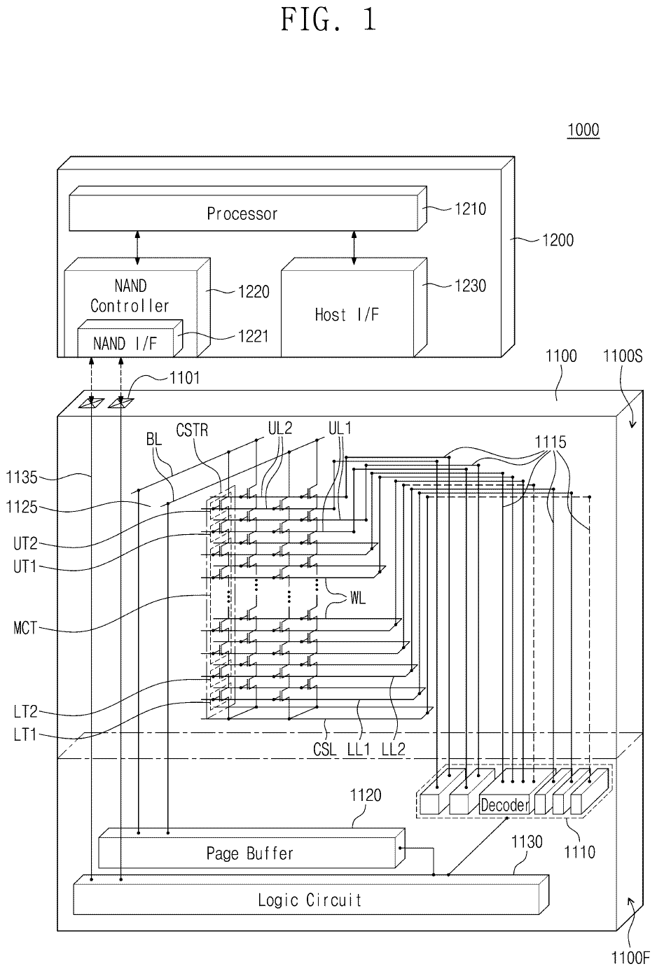

FIG. 1 is a diagram schematically illustrating an electronic system including a three-dimensional semiconductor device according to an embodiment of the disclosure.

Referring to FIG. 1, an electronic system 1000 according to an embodiment of the disclosure may include a three-dimensional semiconductor device 1100 and a controller 1200, which is electrically connected to the three-dimensional semiconductor device 1100. The electronic system 1000 may be a storage device including the three-dimensional semiconductor device 1100 or an electronic device including the storage device. For example, the electronic system 1000 may be a solid state drive (SSD) device, a universal serial bus (USB), a computing system, a medical system, or a communication system, in which the three-dimensional semiconductor device 1100 is provided. In an embodiment, a plurality of three-dimensional semiconductor devices 1100 may be provided.

The three-dimensional semiconductor device 1100 may be a nonvolatile memory device (e.g., a NAND FLASH memory device). The three-dimensional semiconductor device 1100 may include a first structure 1100F and a second structure 1100S on the first structure 1100F. For example, the first structure 1100F may be provided on the second structure 1100S in a vertical direction. However, the disclosure is not limited thereto, and as such, the first structure 1100F may be provided beside the second structure 1100S. For example, the first structure 1100F may be provided adjacent to the second structure 1100S in a horizontal direction (e.g., lateral direction).

The first structure 1100F may be a peripheral circuit structure including a decoder circuit 1110, a page buffer 1120, and a logic circuit 1130. The second structure 1100S may be a memory cell structure including bit lines BL, a common source line CSL, word lines WL, first and second gate upper lines UL1 and UL2, first and second gate lower lines LL1 and LL2, and memory cell strings CSTR between the bit lines BL and the common source line CSL.

In the second structure 1100S, each of the memory cell strings CSTR may include lower transistors LT1 and LT2 adjacent to the common source line CSL, upper transistors UT1 and UT2 adjacent to the bit lines BL, and memory cell transistors MCT between the lower transistors LT1 and LT2 and the upper transistors UT1 and UT2.

In an embodiment, each of the memory cell transistors MCT may include a data storing element having a ferroelectric material. By using the data storing element with the ferroelectric material, it may be possible to realize a three-dimensional semiconductor device that can be operated with low power and with a fast operation speed. In this case, a voltage difference between the word lines WL and channel regions of the memory cell transistors MCT may be adjusted to cause a change in polarization of a dipole of the ferroelectric material, and this may be used to perform a data writing or erasing operation on the memory cell transistors MCT.

In an embodiment, each of the memory cell transistors MCT may be an electrochemical random access memory (ECRAM) device including a data storing element with the solid electrolyte and the ion storage. By using the data storing element with the solid electrolyte and the ion storage, it may be possible to realize a three-dimensional semiconductor memory device that can be operated with relatively low power and with a fast operation speed. In this case, a voltage difference between the word lines WL and the channel regions of the memory cell transistors MCT may be adjusted to change the resistance in the channel regions of the memory cell transistors MCT, and this may be used to perform a data writing or erasing operation on the memory cell transistors MCT.

For example, the upper transistors UT1 and UT2 may include a string selection transistor, and the lower transistors LT1 and LT2 may include a ground selection transistor. The gate lower lines LL1 and LL2 may be used as gate electrodes of the lower transistors LT1 and LT2, respectively. The gate upper lines UL1 and UL2 may be used as respective gate electrodes of the upper transistors UT1 and UT2. In an embodiment, the number of the lower transistors LT1 and LT2 and the number of the upper transistors UT1 and UT2 may be variously changed.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F to the second structure 1100S. The bit lines BL may be electrically connected to the page buffer 1120 through second connection lines 1125, which are extended from the first structure 1100F into the second structure 1100S.

In the first structure 1100F, the decoder circuit 1110 and the page buffer 1120 may execute a control operation on at least one memory cell transistor that is selected from the memory cell transistors MCT. The decoder circuit 1110 and the page buffer 1120 may be controlled by the logic circuit 1130. The three-dimensional semiconductor device 1100 may communicate with the controller 1200 through an input/output pad 1101 electrically connected to the logic circuit 1130. The input/output pad 1101 may be electrically connected to the logic circuit 1130 through an input/output connection line 1135, which is extended from the first structure 1100F to the second structure 1100S.

The first structure 1100F may further include a voltage generator. The voltage generator may generate a program voltage, a read voltage, a pass voltage, a verification voltage, and so forth, which are needed to operate the memory cell strings CSTR. Here, the program voltage may be a relatively high voltage (e.g., 20V to 40V), compared with the read voltage, the pass voltage, and the verification voltage.

For example, the first structure 1100F may include high-voltage transistors and low-voltage transistors. The decoder circuit 1110 may include pass transistors that are connected to the word lines WL of the memory cell strings CSTR. The pass transistors may include high-voltage transistors which can stand a high voltage (e.g., the program voltage) applied to the word lines WL during a programming operation). The page buffer 1120 may also include high-voltage transistors which can stand the high voltage.

The controller 1200 may include a processor 1210, a NAND controller 1220, and a host interface 1230. In an embodiment, a plurality of three-dimensional semiconductor devices 1100 may be provided, and the controller 1200 may be configured to control the three-dimensional semiconductor devices 1100.

The processor 1210 may control overall operations of the electronic system 1000 including the controller 1200. Based on a specific firmware, the processor 1210 may execute operations of controlling the NAND controller 1220 and accessing the three-dimensional semiconductor device 1100. The NAND controller 1220 may include a NAND interface 1221 which is used for communication with the three-dimensional semiconductor device 1100. The NAND interface 1221 may be used to transmit and receive control commands, which will be used to control the three-dimensional semiconductor memory device 1100 and data, which will be written in or read from the memory cell transistors MCT. The host interface 1230 may be configured to allow for communication between the electronic system 1000 and an external host. In an example case in which a control command is provided from an external host through the host interface 1230, the processor 1210 may control the three-dimensional semiconductor device 1100 in response to the control command.

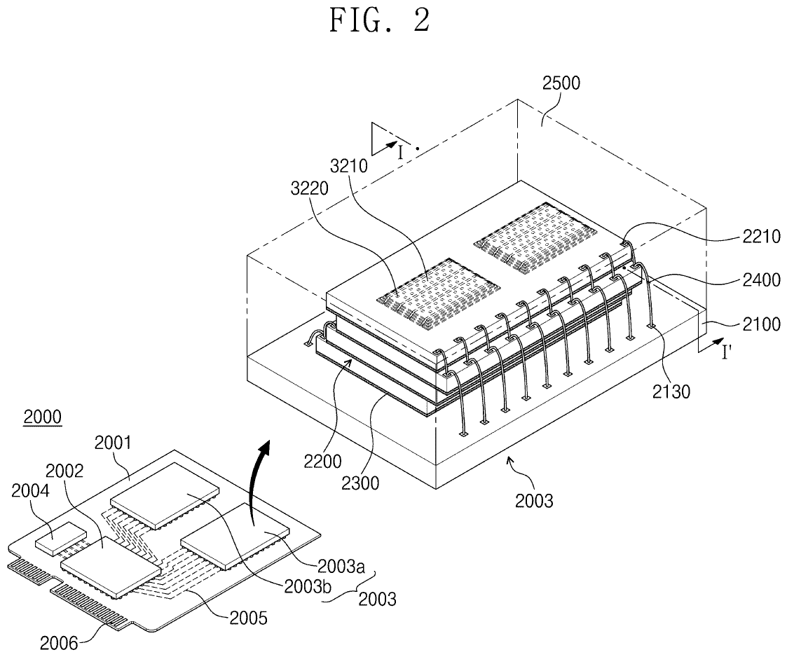

FIG. 2 is a perspective view schematically illustrating an electronic system including a three-dimensional semiconductor device according to an embodiment of the disclosure.

Referring to FIG. 2, an electronic system 2000 may include a main substrate 2001 and a controller 2002, one or more semiconductor packages 2003, and a DRAM 2004, which are mounted on the main substrate 2001. The semiconductor package 2003 and the DRAM 2004 may be connected to the controller 2002 through interconnection patterns 2005, which are formed in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. For example, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In an embodiment, the electronic system 2000 may be driven by an electric power, which is supplied from the external host through the connector 2006. The electronic system 2000 may further include a power management integrated circuit (PMIC) that is configured to separately supply an electric power, which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory that is configured to relieve technical difficulties caused by a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200, which are provided on the package substrate 2100, adhesive layers 2300, which are respectively provided in bottom surfaces of the semiconductor chips 2200, a connection structure 2400, which electrically connects the semiconductor chips 2200 to the package substrate 2100, and a molding layer 2500, which is provided on the package substrate 2100 to cover the semiconductor chips 2200 and the connection structure 2400.

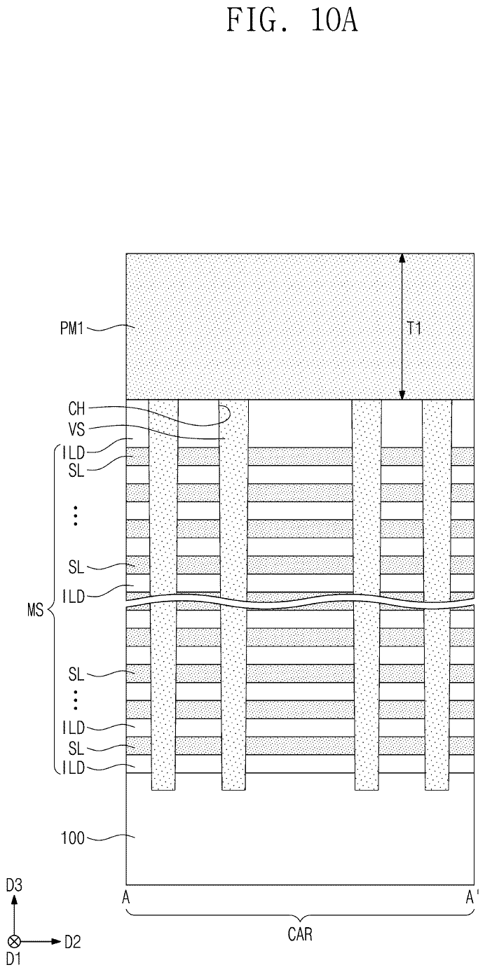

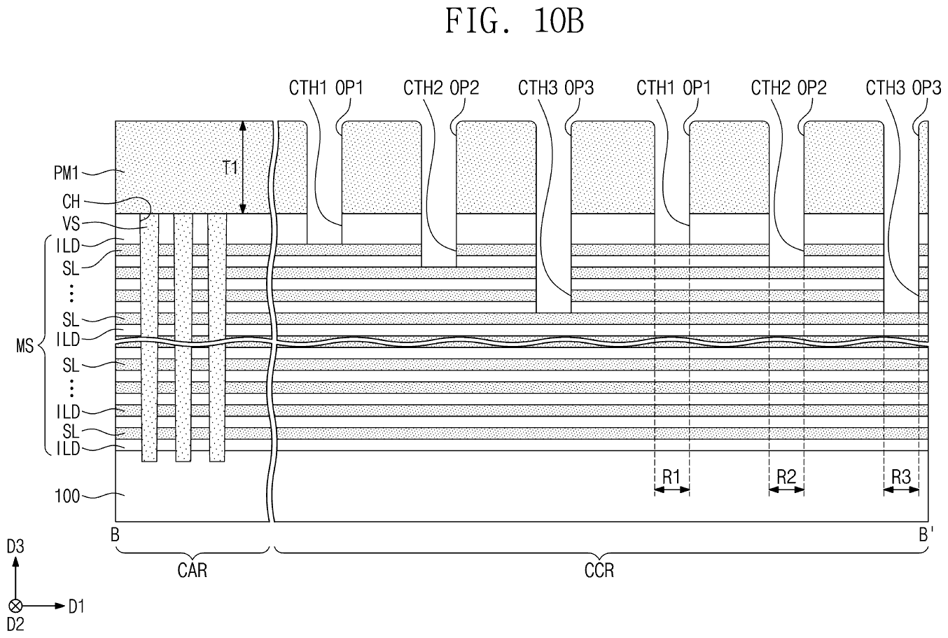

The package substrate 2100 may be a printed circuit board including upper pads 2130. Each of the semiconductor chips 2200 may include an input/output pad 2210. The input/output pad 2210 may correspond to the input/output pad 1101 of FIG. 10. Each of the semiconductor chips 2200 may include stacks 3210 and vertical structures 3220. Each of the semiconductor chips 2200 may include a three-dimensional semiconductor device, which will be described below.

For example, the connection structure 2400 may be a bonding wire electrically connecting the input/output pad 2210 to the upper pads 2130. Thus, in each of the first and second semiconductor packages 2003a and 2003b, the semiconductor chips 2200 may be electrically connected to each other in a bonding wire manner and may be electrically connected to the upper pads 2130 of the package substrate 2100. In an embodiment, the semiconductor chips 2200 in each of the first and second semiconductor packages 2003a and 2003b may be electrically connected to each other by a connection structure including through silicon vias (TSVs), not by the connection structure 2400 provided in the form of bonding wires.

In an embodiment, the controller 2002 and the semiconductor chips 2200 may be included in a single package, but the disclosure is not limited to this example. For example, the controller 2002 and the semiconductor chips 2200 may be mounted on a separate interposer substrate, which is prepared regardless of the main substrate 2001, and may be connected to each other through interconnection lines, which are provided in the interposer substrate.

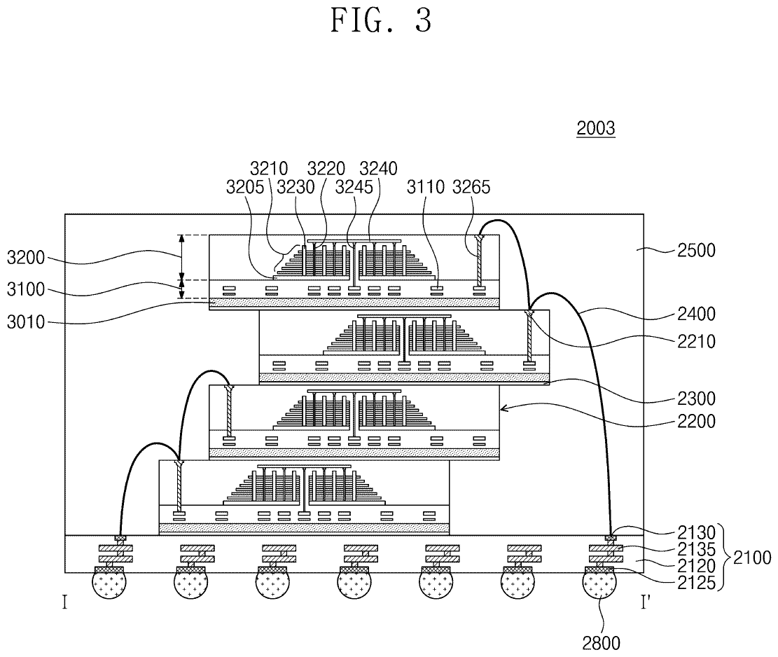

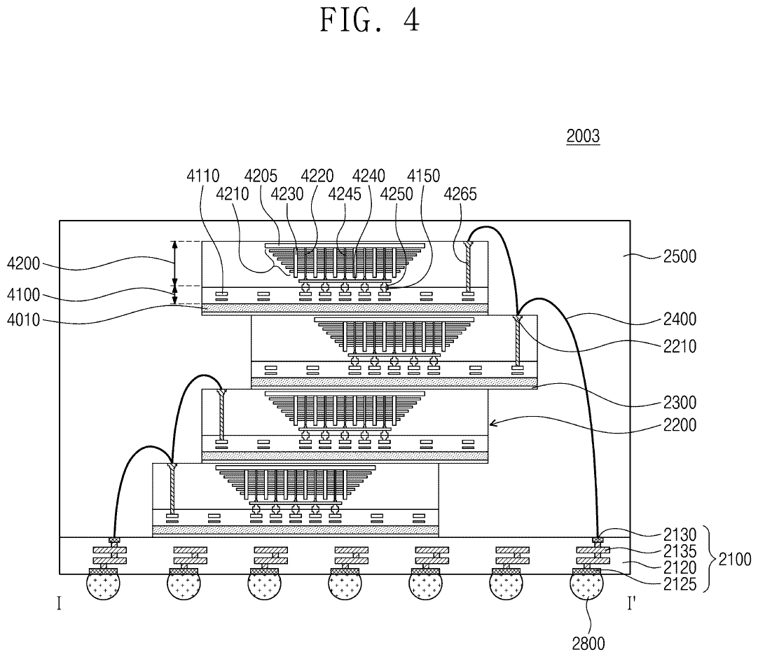

FIGS. 3 and 4 are sectional views, which are taken along a line I-I′ of FIG. 2 to illustrate a semiconductor package including a three-dimensional semiconductor device according to an embodiment of the disclosure.

Referring to FIG. 3, in the semiconductor package 2003, the package substrate 2100 may be a printed circuit board. The package substrate 2100 may include a package substrate body 2120, upper pads 2130, which are provided on a top surface of the package substrate body 2120, lower pads 2125, which are provided on or exposed through a bottom surface of the package substrate body 2120, and internal lines 2135, which are provided in the package substrate body 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 of FIG. 2 through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region including peripheral lines 3110. The second structure 3200 may include a source structure 3205, a stack 3210 on the source structure 3205, the vertical structures 3220 and separation structures 3230 penetrating the stack 3210, bit lines 3240 electrically connected to the vertical structures 3220, and cell contact plugs 3235 electrically connected to the word lines WL of FIG. 1 of the stack 3210.

Each of the semiconductor chips 2200 may be electrically connected to the peripheral lines 3110 of the first structure 3100 and may include penetration lines 3245, which are extended into the second structure 3200. The penetration lines 3245 may be provided outside the stack 3210 and may be further extended to penetrate the stack 3210. Each of the semiconductor chips 2200 may further include the input/output pad 2210 electrically connected to the peripheral lines 3110 of the first structure 3100.

Referring to FIG. 4, the semiconductor chips 2200 of the semiconductor package 2003 may include a semiconductor substrate 4010, a first structure 4100 on the semiconductor substrate 4010, and a second structure 4200, which is placed on and bonded to the first structure 4100 in a wafer bonding method.

The first structure 4100 may include a peripheral circuit region including a peripheral line 4110 and first junction structures 4150. The second structure 4200 may include a source structure 4205, a stack 4210 between the source structure 4205 and the first structure 4100, vertical structures 4220 and a separation structure 4230 penetrating the stack 4210, and second junction structures 4250, which are respectively and electrically connected to the vertical structures 4220 and the word lines WL of FIG. 1 of the stack 4210. For example, the second junction structures 4250 may be electrically connected to the vertical structures 4220 and the word lines WL of FIG. 1 through bit lines 4240 and cell contact plugs 4235, which are respectively and electrically connected to the vertical structures 4220 and the word lines WL of FIG. 1. The first junction structures 4150 of the first structure 4100 and the second junction structures 4250 of the second structure 4200 may be in contact with each other and may be bonded to each other. For example, the first and second junction structures 4150 and 4250 may be formed of or include copper.

Referring back to FIGS. 3 and 4, the first structures 3100 and 4100 and the second structures 3200 and 4200 may correspond to the first and second structures 1100F and 1100S of FIG. 1. The semiconductor chips 2200 may be electrically connected to each other by the connection structures 2400, which are provided in the form of the bonding wires, but the disclosure is not limited to this example. For example, the semiconductor chips 2200 may be electrically connected to each other through penetration electrodes penetrating the semiconductor chips 2200.

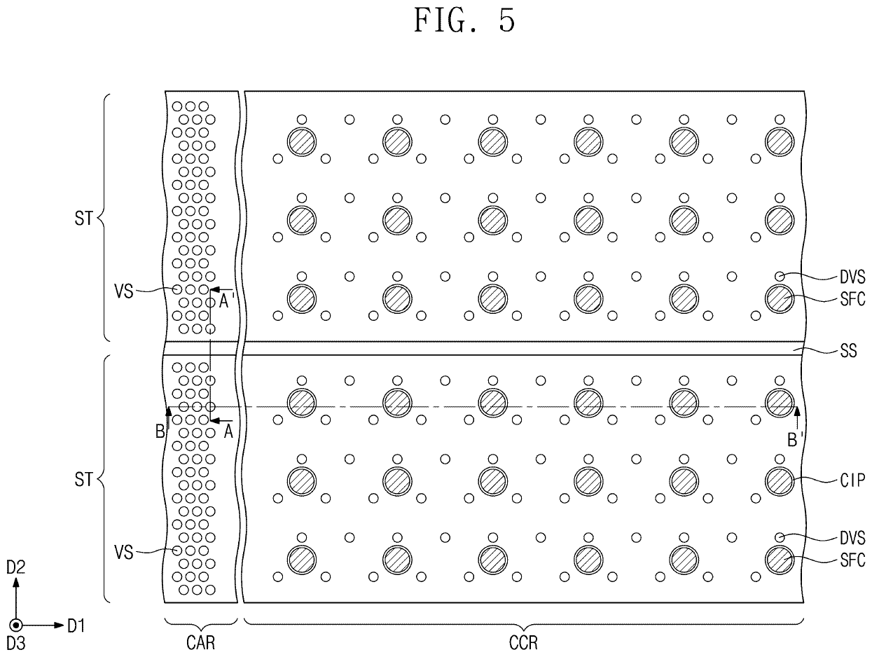

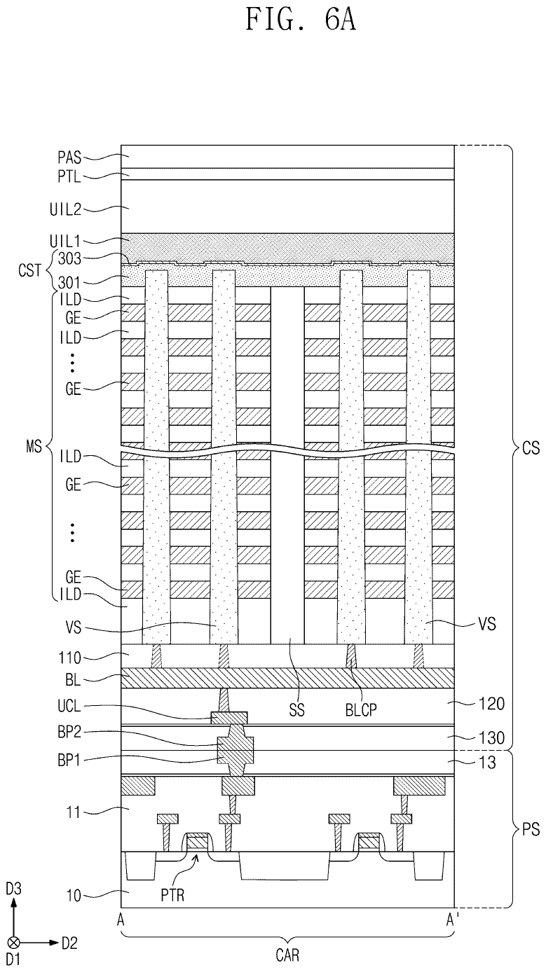

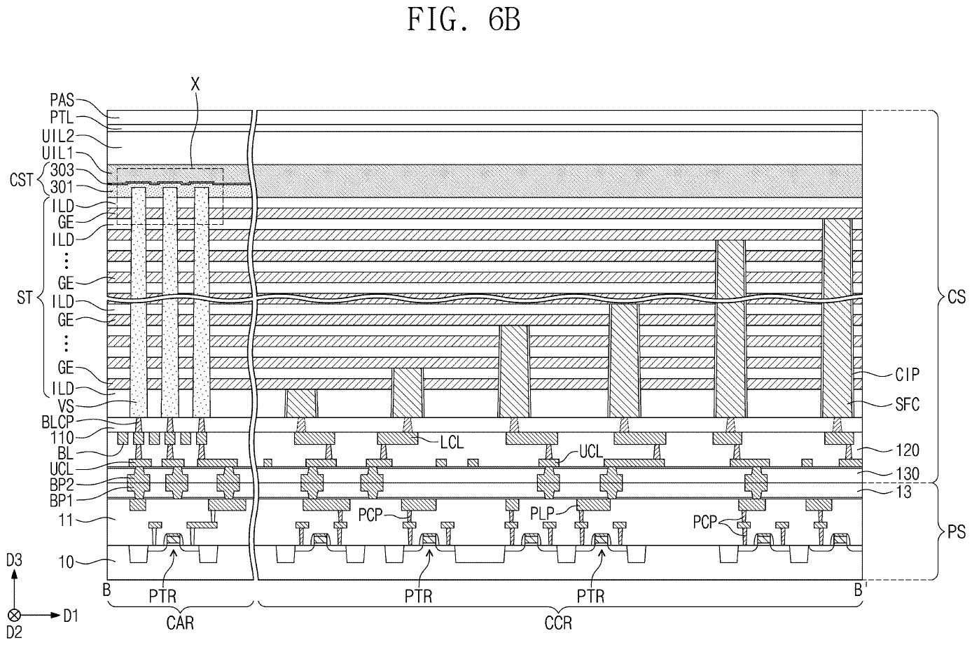

FIG. 5 is a plan view illustrating a three-dimensional semiconductor device according to an embodiment of the disclosure. FIGS. 6A and 6B are sectional views, which are taken along lines A-A′ and B-B′ of FIG. 5 to illustrate a three-dimensional semiconductor device according to an embodiment of the disclosure.

Referring to FIGS. 5, 6A, and 6B, the three-dimensional semiconductor device may include a peripheral circuit structure PS and a cell array structure CS, which are sequentially stacked on a substrate 10. For example, the substrate 10 may correspond to the semiconductor substrates 3010 of FIGS. 3 and 4010 of FIG. 4. The peripheral circuit structure PS may correspond to the first structures 3100 of FIGS. 3 and 4100 of FIG. 4. The cell array structure CS may correspond to the second structures 3200 of FIGS. 3 and 4200 of FIG. 4. For example, the three-dimensional semiconductor device according to an embodiment of the disclosure may be a vertical-type NAND FLASH memory device.

According to an embodiment, since the cell array structure CS are bonded to the peripheral circuit structure PS, the cell capacity per unit area in the three-dimensional semiconductor device may be increased. According to an embodiment, the peripheral circuit structure PS and the cell array structure CS may be separately fabricated and then may be coupled to each other, and in this case, it may be possible to prevent peripheral transistors PTR from being damaged by several thermal treatment processes. Thus, the electrical and reliability characteristics of the three-dimensional semiconductor device may be improved.

According to an embodiment, the substrate 10 may be at least one of a silicon substrate, a silicon-germanium substrate, a germanium substrate, and a single-crystalline epitaxial layer grown from a single-crystalline silicon substrate, but the disclosure is not limited to this example. A top surface of the substrate 10 may be parallel to a first direction D1 and a second direction D2, which are not parallel to each other. The top surface of the substrate 10 may be perpendicular to a third direction D3. For example, the first to third directions D1, D2, and D3 may be orthogonal to each other. According to example embodiments, the first direction D1 and the second direction D2 may be referred to as a horizontal direction, and the third direction D3 may be referred to as a vertical direction.

The substrate 10 may include a cell array region CAR and a connection region CCR. The cell array region CAR may be adjacent to the cell array region CAR and may extended in the first direction D1. For example, the cell array region CAR may be a region, on which vertical structures VS to be described below will be provided. The connection region CCR may be a region, on which electrode contacts SFC to be described below will be provided. In an embodiment, a plurality of cell array regions CAR may be provided, and the connection region CCR may be placed between the plurality of cell array regions CAR. For example, a connection region CCR may be provided between a first cell array region and a second cell array region.

The peripheral circuit structure PS may include the peripheral transistors PTR on the substrate 10, peripheral plugs PCP, peripheral circuit lines PLP electrically connected to the peripheral transistors PTR via the peripheral plugs PCP, first bonding pads BP1 electrically connected to the peripheral circuit lines PLP, and lower insulating layers. For example, the lower insulating layers may be provided on one or more the peripheral transistors PTR, the peripheral plugs PCP, the peripheral circuit lines PLP, and the first bonding pads BP1. For example, one or more insulating layers may be provided to cover the peripheral transistors PTR, the peripheral plugs PCP, the peripheral circuit lines PLP, and the first bonding pads BP1. However, the disclosure is not limited thereto, and as such, according to an embodiment, in the peripheral circuit structure PS, one or more components may be added, omitted or combined.

The peripheral transistors PTR may be provided on an active region of the substrate 10. The peripheral transistors PTR may include, but is not limited to, row and column decoders, a page buffer, and a control circuit. For example, the peripheral transistors PTR may include, but is not limited to, NMOS transistors and PMOS transistors.

The peripheral plugs PCP may be electrically connected to the peripheral transistors PTR. For example, the peripheral plugs PCP may be connected to the source and drain regions of each of the peripheral transistors PTR. The peripheral circuit lines PLP may be electrically connected to the peripheral transistors PTR through the peripheral plugs PCP. For example, the peripheral plugs PCP and the peripheral circuit lines PLP may be formed of or include at least one of metallic materials and metal nitride materials. The metallic material may include, but is not limited to, Ti, Mo, W, Cu, Al, Au, Ta, Ru, and Ir and the metal nitride material may include, but is not limited to, titanium nitride or tantalum nitride.

The lower insulating layers may be located on the substrate 10. The lower insulating layers may include a first lower insulating layer 11 and a second lower insulating layer 13 on the first lower insulating layer 11. The first lower insulating layer 11 may be provided on the peripheral transistors PTR, the peripheral plugs PCP, the peripheral circuit lines PLP. For example, the first lower insulating layer 11 may cover the peripheral transistors PTR, the peripheral plugs PCP, the peripheral circuit lines PLP. The second lower insulating layer 13 may be provided to on a top surface of the first lower insulating layer 11 and side surfaces of the first bonding pads BP1. For example, the second lower insulating layer 13 may be provided to cover the top surface of the first lower insulating layer 11 and the side surfaces of the first bonding pads BP1 and to expose top surfaces of the first bonding pads BP1. For example, a top surface of the second lower insulating layer 13 may be coplanar with the top surfaces of the first bonding pads BP1. In an embodiment, the peripheral circuit structure PS may further include an etch stop layer between the first lower insulating layer 11 and the second lower insulating layer 13.

The cell array structure CS may be placed on the peripheral circuit structure PS. The cell array structure CS may include a first interlayer insulating layer 110, a second interlayer insulating layer 120, a third interlayer insulating layer 130, a stack ST, the vertical structures VS, and the electrode contacts SFC. In addition, the cell array structure CS may further include various elements, which are provided in the first to third interlayer insulating layers 110, 120, and 130 to electrically connect the cell array structure CS to the peripheral circuit structure PS.

According to an embodiment, a third interlayer insulating layer 130 may be provided on the second lower insulating layer 13 of the peripheral circuit structure PS. For example, the third interlayer insulating layer 130 may be placed on the second lower insulating layer 13 of the peripheral circuit structure PS to cover the second lower insulating layer 13. Second bonding pads BP2 may be provided in the third interlayer insulating layer 130. The second bonding pads BP2 may be bonded to corresponding ones of the first bonding pads BP1 in a hybrid bonding manner. According to example embodiments, the hybrid bonding structure may mean a bonding structure which is formed by two materials, which are of the same kind and are fused at an interface therebetween. Thus, the first and second bonding pads BP1 and BP2 may be bonded to each other to form a single object.

A second interlayer insulating layer 120 may be placed on the third interlayer insulating layer 130. Upper conductive lines UCL, lower conductive lines LCL, and the bit lines BL may be provided in the second interlayer insulating layer 120. The lower conductive lines LCL and the bit lines BL may be placed on the upper conductive lines UCL. For example, the upper conductive lines UCL may be placed in a lower portion of the second interlayer insulating layer 120, and the lower conductive lines LCL and the bit lines BL may be placed in an upper portion of the second interlayer insulating layer 120. In addition, the bit lines BL may be located on the cell array region CAR, and the lower conductive lines LCL may be located on the connection region CCR. The upper conductive lines UCL may be electrically connected to the lower conductive lines LCL or the bit lines BL, respectively, and may be electrically connected to the second bonding pads BP2, respectively.

In an embodiment, the cell array structure CS may further include an etch stop layer between the third interlayer insulating layer 130 and the second interlayer insulating layer 120.

A first interlayer insulating layer 110 may be placed on the second interlayer insulating layer 120. Bit line plugs BLCP and conductive line plugs CLCP may be provided in the first interlayer insulating layer 110. The bit line plugs BLCP may be placed between the vertical structures VS and the bit lines BL to electrically connect them to each other. The conductive line plugs CLCP may be placed between the electrode contacts SFC and the lower conductive lines LCL to electrically connect them to each other. For example, the bit line plugs BLCP may be placed on the cell array region CAR, and the conductive line plugs CLCP may be placed on the connection region CCR.

The stack ST may be placed on the first interlayer insulating layer 110. The stack ST may be extended in the first direction D1. For example, the stack ST may be a memory cell block that is configured to store data. In an embodiment, a plurality of stacks ST may be provided, and a separation structure SS to be described below may be provided therebetween.

The stack ST may include gate electrodes GE and interlayer insulating layers ILD, which are alternately stacked in the third direction D3. For example, the gate electrodes GE and the interlayer insulating layers ILD may be placed at different levels. According to example embodiments, the level may mean a height from the top surface of the substrate 10 measured in the third direction D3. The gate electrodes GE may have substantially the same thickness. The lowermost one of the interlayer insulating layers ILD may be thicker than the others of the interlayer insulating layers ILD, but the disclosure is not limited to this example. The gate electrodes GE may be formed of or include at least one of, for example, doped semiconductor materials (e.g., doped silicon), metallic materials (e.g., tungsten, copper, or aluminum), conductive metal nitrides (e.g., titanium nitride or tantalum nitride), or transition metals (e.g., titanium or tantalum). The interlayer insulating layers ILD may be formed of or include at least one of silicon oxide and/or low-k dielectric materials.

Each of the gate electrodes GE and the interlayer insulating layers ILD may be extended in the first direction D1 and may have a length in the first direction D1. The lengths of the gate electrodes GE and the interlayer insulating layers ILD in the first direction D1 may be substantially equal to each other. That is, each of the gate electrodes GE and the interlayer insulating layers ILD may have substantially the same horizontal length. In other words, the stack ST may not have a staircase structure on the connection region CCR. Thus, the length of the stack ST in the first direction D1 may be decreased on the connection region CCR. Accordingly, it may be possible to reduce the size of the three-dimensional semiconductor device.

In an embodiment, the stack ST may include a plurality of stacks stacked in the third direction D3. For example, the stack ST may include a first stack and a second stack on the first stack. The first stack and the second stack may be vertically overlapped with each other. Thus, the stack ST may be formed to have an increased height in the third direction D3. However, the disclosure is not limited to a first stack and a second stack, and as such, a number of overlapping stacks may be more than two.

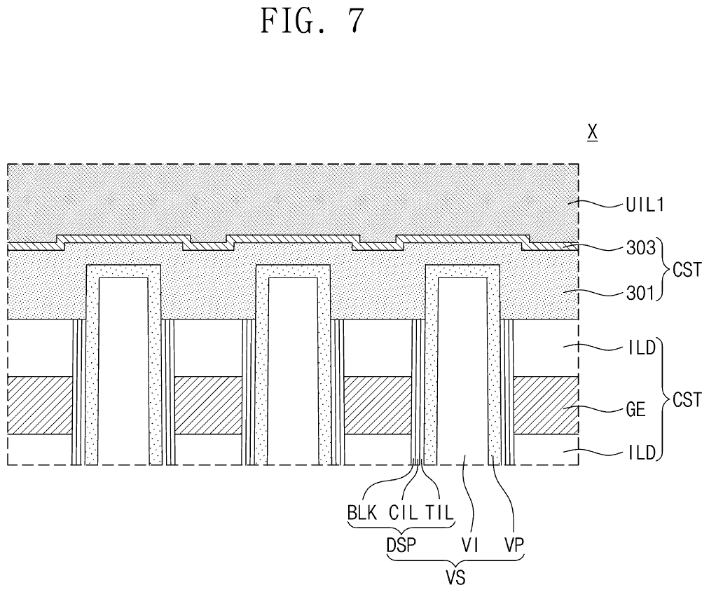

The vertical structures VS may be provided on the cell array region CAR. When viewed in a plan view, the vertical structures VS may be arranged in a specific direction or in a zigzag shape. The vertical structures VS may be provided to penetrate the stack ST. Each of the vertical structures VS may have a shape extended in the third direction D3 and may be connected to a source structure CST, which will be described below. For example, each of the vertical structures VS may be extended into the source structure CST to penetrate a portion of the source structure CST. The vertical structures VS may be electrically connected to the bit lines BL through the bit line plugs BLCP. Each of the vertical structures VS may be provided to have a multi-layered structure, and the vertical structures VS will be described in more detail with reference to FIG. 7.

The electrode contacts SFC may be provided on the connection region CCR. When viewed in a plan view, the electrode contacts SFC on the connection region CCR may be spaced apart from each other in the first direction D1 and the second direction D2. The electrode contacts SFC may be provided to penetrate a portion of the stack ST or may be extended into the stack ST. For example, the electrode contacts SFC may be formed of or include at least one of metallic materials, conductive metal nitride materials, or transition metal materials (e.g., titanium and tantalum). The metallic materials may include, but is not limited to, tungsten, copper, and aluminum. The metal nitride materials may include, but is not limited to, titanium and tantalum.

Each of the electrode contacts SFC may be connected to one of the gate electrodes GE of the stack ST. For example, the electrode contacts SFC may be electrically connected to corresponding ones of the gate electrodes GE of the stack ST. Since the gate electrodes GE of the stack ST are stacked in the third direction D3 and are located at different levels, the vertical lengths of the electrode contacts SFC may be different from each other in the third direction D3. A vertical length of each of the electrode contacts SFC may be smaller than a length of the stack ST in the third direction D3. In other words, the electrode contacts SFC may not fully penetrate the stack ST.

Contact insulating patterns CIP may be provided between the electrode contacts SFC and the stack ST. Each of the contact insulating patterns CIP may be extended along the side surface of each of the electrode contacts SFC or in the third direction D3. When viewed in a plan view, each of the contact insulating patterns CIP may enclose each of the electrode contacts SFC. For example, the contact insulating patterns CIP may be formed of or include at least one of insulating materials. The insulating materials may include, but is not limited to, silicon oxide and/or low-k dielectric materials. Thus, the electrode contacts SFC may be electrically disconnected from undesired gate electrodes GE.

Dummy vertical structures DVS may be further provided on the connection region CCR. When viewed in a plan view, the dummy vertical structures DVS may be provided to be adjacent to the electrode contacts SFC. For example, each of the electrode contacts SFC may be placed between adjacent ones of the dummy vertical structures DVS. Similar to the vertical structures VS, the dummy vertical structures DVS may be provided to penetrate the stack ST. Unlike the vertical structures VS, the dummy vertical structures DVS may be composed of a single layer, but the disclosure is not limited to this example.

On the cell array region CAR, the source structure CST may be provided on the stack ST. The source structure CST may correspond to the common source lines 3205 and 4205 of FIGS. 3 and 4. The source structure CST may be provided on portions of the vertical structures VS protruding from the stack ST. For example, the source structure CST may cover portions of the vertical structures VS protruding from the stack ST. The source structure CST may include a first source conductive pattern 301 and a second source conductive pattern 303. The second source conductive pattern 303 may be provided on the first source conductive pattern 301. For example, the second source conductive pattern 303 may be placed on the first source conductive pattern 301 to cover the first source conductive pattern 301. The second source conductive pattern 303 may be spaced apart from the vertical structures VS in the third direction D3. For example, the first source conductive pattern 301 may be formed of or include at least one of n-and p-type doped semiconductor materials. The second source conductive pattern 303 may include at least one of metallic materials or metal nitride materials.

A first upper insulating layer UIL1 may be provided on the stack ST. For example, on the cell array region CAR, the first upper insulating layer UIL1 may be provided on the source structure CST. For example, on the cell array region CAR, the first upper insulating layer UIL1 may cover the source structure CST. For example, on the connection region CCR, the first upper insulating layer UIL1 may be provided on the stack ST. For example, on the connection region CCR, the first upper insulating layer UIL1 may cover the stack ST. For example, the first upper insulating layer UIL1 may be formed of or include at least one of high-k dielectric materials or tetraethyl orthosilicate (TEOS).

A second upper insulating layer UIL2, a protection layer PTL, and a passivation layer PAS may be sequentially provided on the first upper insulating layer UIL1. For example, the second upper insulating layer UIL2 may be formed of or include at least one of SiN, HDP, or TEOS. The protection layer PTL may be formed of or include at least one of metal oxide materials and high-k dielectric materials. The metal oxide materials may include, but is not limited to, aluminum oxide, zirconium oxide, hafnium oxide, tantalum oxide, and hafnium aluminum oxide. The passivation layer PAS may be formed of or include a polyimide-based material (e.g., photo sensitive polyimide (PSPI)).

In a three-dimensional semiconductor device according to an embodiment of the disclosure, some of the electrode contacts SFC may be formed using a plurality of stacked mask patterns. Thus, it may be possible to prevent a bowing phenomenon in the step of forming the electrode contacts SFC. In addition, it may be possible to increase the lengths of the stack ST and the electrode contacts SFC in the third direction D3. Accordingly, it may be possible to improve the integration density of the three-dimensional semiconductor device. In addition, the electrical and reliability characteristics of the three-dimensional semiconductor device may be improved.

FIG. 7 is an enlarged view illustrating a portion (e.g., X of FIG. 6B) of a three-dimensional semiconductor device according to an embodiment of the disclosure.

Referring to FIG. 7, each of the vertical structures VS may include a vertical semiconductor pattern VP and a data storage pattern DSP and a gapfill insulating pattern VI. For example, the data storage pattern DSP may be provided on a side surface of the vertical semiconductor pattern VP. For example, the data storage pattern DSP may enclose the side surface of the vertical semiconductor pattern VP. For example, the gapfill insulating pattern VI may fill an inner space of the vertical semiconductor pattern VP.

The vertical semiconductor pattern VP may have a shape that is extended from the stack ST into the first source conductive pattern 301 of the source structure CST. For example, a top end of the vertical semiconductor pattern VP may have a shape protruding from the stack ST. For example, an upper surface of the vertical semiconductor pattern VP may be higher than an upper surface of the stack ST. The top end of the vertical semiconductor pattern VP may have a top-closed pipe or macaroni shape. In addition, the top end of the vertical semiconductor pattern VP may have an inverted ‘U’-shaped section, but the disclosure is not limited to this example. For example, the vertical semiconductor pattern VP may include at least one of a doped semiconductor material, an undoped or intrinsic semiconductor material, and a polycrystalline semiconductor material.

The data storage pattern DSP may be placed between the vertical semiconductor pattern VP and the stack ST. The data storage pattern DSP may not be extended into the first source conductive pattern 301 of the source structure CST. For example, the top surface of the data storage pattern DSP may be substantially coplanar with the top surface of the stack ST. The data storage pattern DSP may be a top-open pipe or macaroni shape. Thus, the data storage pattern DSP may not be in contact with the top end of the vertical semiconductor pattern VP.

The data storage pattern DSP may include a tunnel insulating layer TIL, a charge storing layer CIL, and a blocking insulating layer BLK, which are sequentially stacked on a side surface of the vertical semiconductor pattern VP. The tunnel insulating layer TIL may be in contact with the side surface of the vertical semiconductor pattern VP. The blocking insulating layer BLK may be in contact with the stack ST. The charge storing layer CIL may be placed between the tunnel insulating layer TIL and the blocking insulating layer BLK. Each of the tunnel insulating layer TIL, the charge storing layer CIL, and the blocking insulating layer BLK may be extended in a vertical direction, between the vertical semiconductor pattern VP and the stack ST. In an embodiment, the Fowler-Nordheim (FN) tunneling phenomenon, which is caused by a voltage difference between the vertical semiconductor pattern VP and the gate electrodes GE of the stack ST, may be used to store or change data in the data storage pattern DSP. For example, each of the blocking and tunnel insulating layers BLK and TIL may be formed of or include silicon oxide, and the charge storing layer CIL may be formed of or include at least one of silicon nitride or silicon oxynitride.

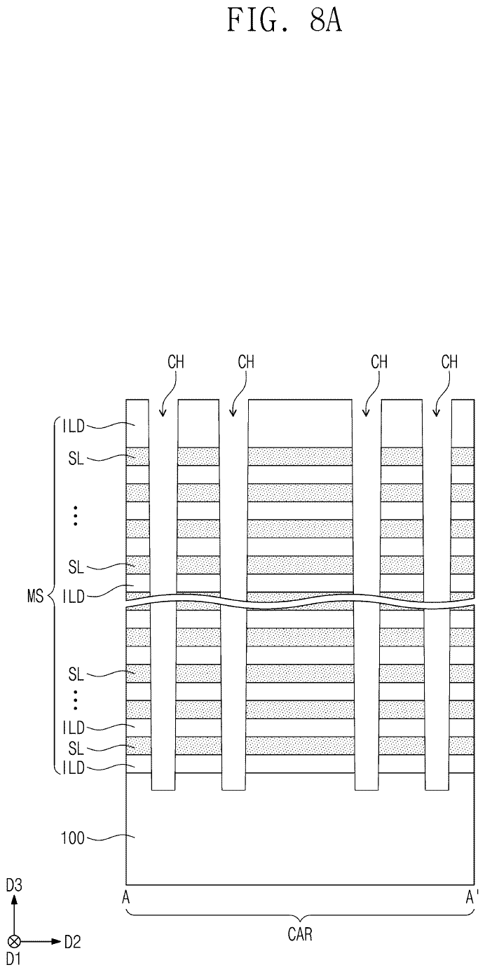

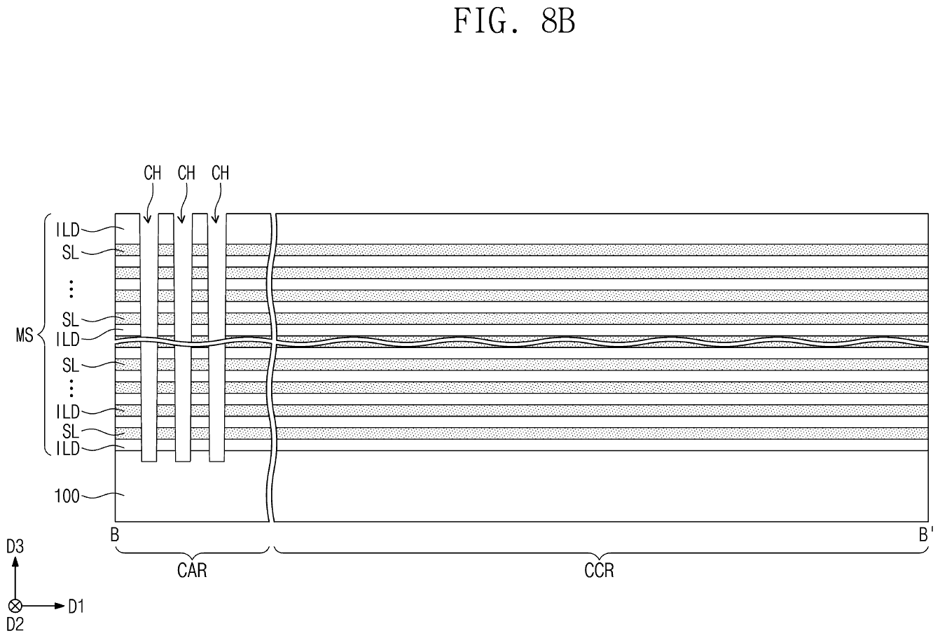

FIGS. 8A, 8B, 9A, 9B, 10A, 10B, 11A, 11B, 12A, 12B, 13A, 13B, 14A, 14B, 15A, 15B, 16A and 16B are diagrams illustrating a method of fabricating a three-dimensional semiconductor device, according to an embodiment of the disclosure. FIGS. 8A, 9A, 10A, 11A, 12A, 13A, 14A, 15A, and 16A are sectional views taken along a line A-A′ of FIG. 5. FIGS. 8B, 9B, 10B, 11B, 12B, 13B, 14B, 15B, and 16B are sectional views taken along a line B-B′ of FIG. 5.

Referring to FIGS. 8A and 8B, a carrier substrate 100 including the cell array region CAR and the connection region CCR may be provided. The carrier substrate 100 may include the cell array region CAR and the connection region CCR, which is extended from the cell array region CAR in the first direction D1. The carrier substrate 100 may be at least one of a silicon substrate, a silicon-germanium substrate, a germanium substrate, and a single-crystalline epitaxial layer grown from a single-crystalline silicon substrate, but the disclosure is not limited to this example.

A mold structure MS may be formed on the carrier substrate 100. The formation of the mold structure MS may include alternately forming the interlayer insulating layers ILD and the sacrificial layers SL in the third direction D3. For example, the interlayer insulating layers ILD and the sacrificial layers SL may be formed using a chemical vapor deposition (CVD) process or an atomic layer deposition (ALD) process. The sacrificial layers SL may have substantially the same thickness in the third direction D3. The uppermost one of the interlayer insulating layers ILD may be thicker in the third direction D3 than the other interlayer insulating layers ILD. However, the disclosure is not limited to this example.

The sacrificial layers SL and the interlayer insulating layers ILD may have an etch selectivity with respect to each other. Thus, the interlayer insulating layers ILD may not be removed in a subsequent process of removing the sacrificial layers SL and may remain. For example, the sacrificial layers SL may be formed of or include silicon nitride, and the interlayer insulating layers ILD may be formed of or include silicon oxide.

Channel holes CH may be formed to penetrate the mold structure MS. The channel holes CH may be provided on the cell array region CAR. The formation of the channel holes CH may include forming a mask pattern on the mold structure MS, performing an etching process using the mask pattern on the mold structure MS, and removing the mask pattern. As a result of the etching process, the carrier substrate 100 may be exposed through the channel holes CH. In addition, the etching process may be performed to remove a portion of the carrier substrate 100. Thus, a top surface of the carrier substrate 100 may be placed at a level higher than a bottom surface of each of the channel holes CH.

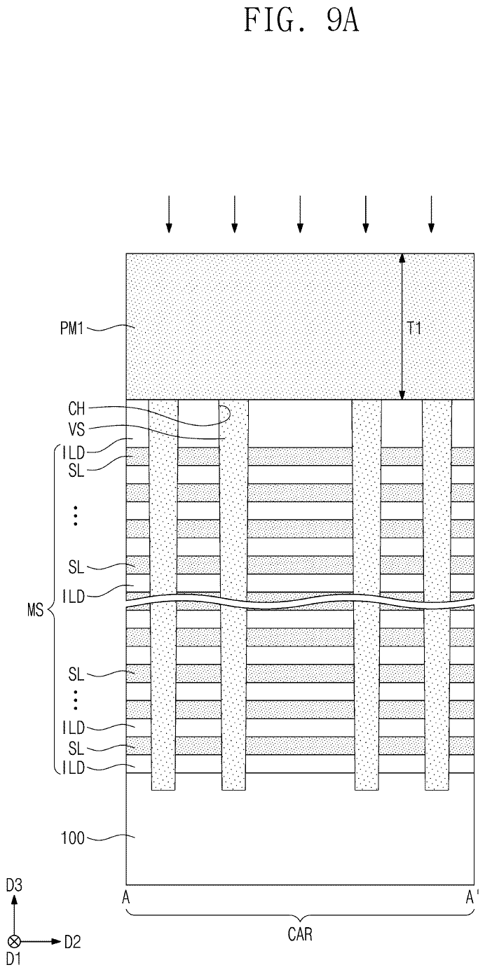

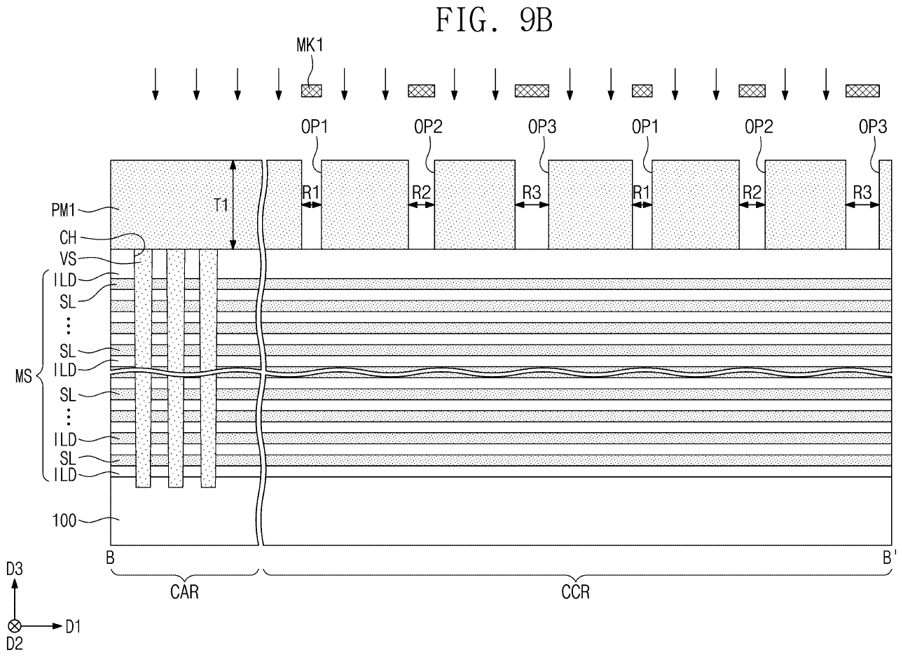

Referring to FIGS. 9A and 9B, each of the vertical structures VS may be formed in each of the channel holes CH. The formation of the vertical structures VS may include sequentially forming the data storage pattern DSP, the vertical semiconductor pattern VP, and the gapfill insulating pattern VI of FIG. 7 in the channel holes CH. Each of the data storage pattern DSP, the vertical semiconductor pattern VP, and the gapfill insulating pattern VI may be formed by a chemical vapor deposition process or an atomic layer deposition process. In an embodiment, the dummy vertical structures DVS described with reference to FIG. 5 may be formed concurrently with the vertical structures VS.

Thereafter, a first mask pattern PM1 may be formed on the mold structure MS. The formation of the first mask pattern PM1 may include forming a first photoresist layer, performing a bake process on the first photoresist layer, and performing an exposure process on the first photoresist layer.

The first photoresist layer of uniform thickness may be formed on the mold structure MS by a spin coating process. The spin coating process may be a process of spinning the carrier substrate 100, which is coated with a photoresist material, at a high speed. In an embodiment, the spin coating process may be used to form not only the first photoresist layer but also an organic planarization layer or an anti-reflection coating layer, which is provided below the first photoresist layer, as well as a top coating layer, which is provided on the first photoresist layer.

Thereafter, a bake process may be performed on the first photoresist layer. For example, the bake process may include a soft bake process. The soft bake process may be referred to as a pre-bake process and may be performed to remove the organic solvent from the first photoresist layer and enhance an adhesion property between the first photoresist layer and the carrier substrate 100. The soft bake process may be performed at a relatively low temperature.

An exposure process using a first photomask MK1 may be performed after the bake process. The exposure process may include placing the first photomask MK1 on the first photoresist layer and exposing the first photoresist layer to an electron beam or light, which is irradiated through the first photomask MK1. A developing process may be further performed on the exposed first photoresist layer. In the developing process, a region of the first photoresist layer, whether exposed or unexposed, may be removed using developing solution. As a result, the first mask pattern PM1 may be formed from the first photoresist layer.

The first mask pattern PM1 may have, for example, first openings OP1, second openings OP2, and third openings OP3. The first to third openings OP1, OP2, and OP3 may be provided on the connection region CCR. Each of the first openings OP1 may have a first diameter R1 in a horizontal direction. Each of the second openings OP2 may have a second diameter R2 in a horizontal direction. Each of the third openings OP3 may have a third diameter R3 in a horizontal direction. The first diameter R1 of the first openings OP1 may be smaller than the second diameter R2 of the second openings OP2 and the third diameter R3 of the third openings OP3. The second diameter R2 of the second openings OP2 may be smaller than the third diameter R3 of the third openings OP3. That is, the third diameter R3 of the third openings OP3 may be the largest, and the first diameter R1 of the first openings OP1 may be the smallest.

In addition, the first mask pattern PM1 may have a first thickness T1 in the third direction D3. If the first thickness T1 of the first mask pattern PM1 is large, it may be possible to etch the mold structure MS deeply without a bowing phenomenon during the etching process using the first mask pattern PM1. However, the larger the first thickness T1 of the first mask pattern PM1, the more difficult the formation of the first to third openings OP1, OP2, and OP3 become. This means that it is necessary to adjust the first thickness T1 of the first mask pattern PM1 within an appropriate thickness range. For example, the first thickness T1 of the first mask pattern PM1 may range from about 2 μm to about 3 μm.

Referring to FIGS. 10A and 10B, a first etching process using the first mask pattern PM1 as an etch mask may be performed. For example, the first etching process may be an anisotropic etching process. During the first etching process, a portion of the mold structure MS may be etched to form first contact holes CTH1, second contact holes CTH2, and third contact holes CTH3 in the mold structure MS.

The difference in the diameters of the first to third openings OP1, OP2, and OP3 may cause a variation in the amount or depth of the mold structure MS etched during the first etching process. In other words, the first to third contact holes CTH1, CTH2, and CTH3, which are formed below the first to third openings OP1, OP2, and OP3 during the first etching process, may have different depths from each other. For example, since the first openings OP1 have the smallest diameter, the first contact holes CTH1, which are formed below the first openings OP1, may have the smallest depth. Since the third openings OP3 have the largest diameter, the third contact holes CTH3, which are formed below the third openings OP3, may have the largest depth.

As a result of the first etching process, diameters of the first to third openings OP1, OP2, and OP3 may be increased. For example, a first diameter R1 of the first openings OP1, a second diameter R2 of the second openings OP2, and a third diameter R3 of the third openings OP3 may be increased. For example, the diameters of the first to third openings OP1, OP2, and OP3 may increase corresponding to the depth of the respective contact hole. Thus, the first diameter R1 of the first openings OP1, the second diameter R2 of the second openings OP2, and the third diameter R3 of the third openings OP3 may be substantially equal to each other. Accordingly, the diameters of the first to third contact holes CTH1, CTH2, and CTH3 may also be substantially equal to each other, but the disclosure is not limited to this example. For example, the diameter of each of the first to third contact holes CTH1, CTH2, and CTH3 may range from about 400 nm to about 500 nm.

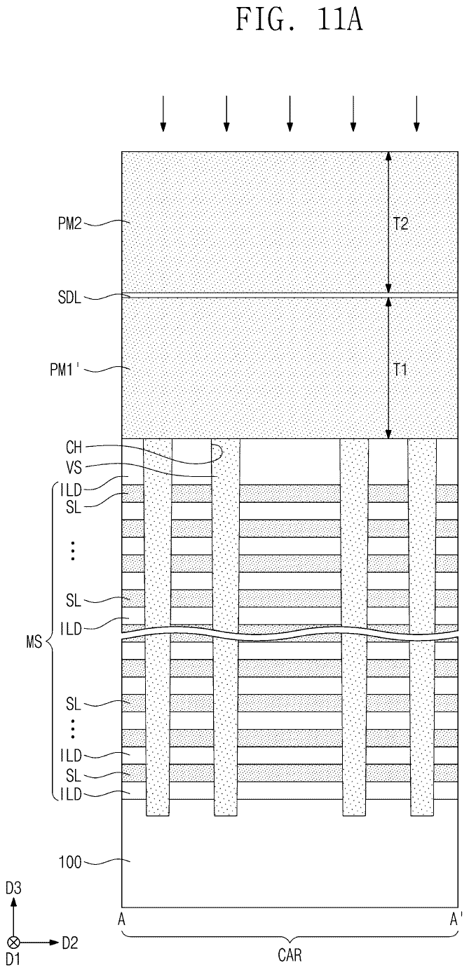

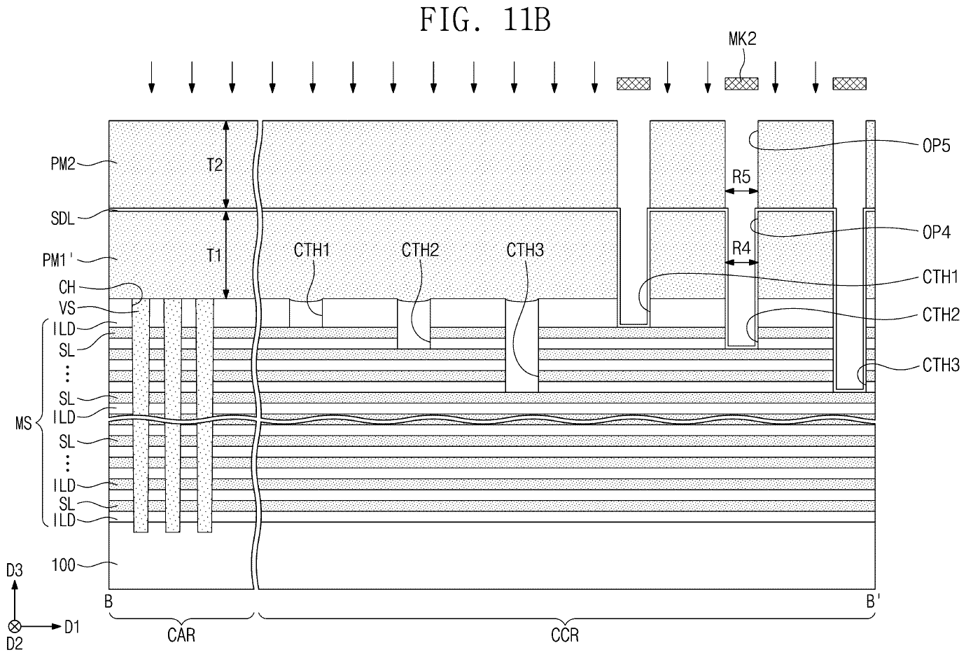

Referring to FIGS. 11A and 11B, the first mask pattern PM1 used in the first etching process may be removed, and a new first mask pattern PM1′ may be formed. The first mask pattern PM1′ may be provided on the first to third contact holes CTH1, CTH2, and CTH3. For example, the first mask pattern PM1′ may cover the first to third contact holes CTH1, CTH2, and CTH3 adjacent to (or closer to) the cell array region CAR. For example, in FIG. 11, the first three contact holes CTH1, CTH2, and CTH3 may be considered as being adjacent to (or closer to) the cell array region CAR, but the disclosure is not limited thereto. The formation of the first mask pattern PM1′ may be substantially the same as that described with reference to FIGS. 9A and 9B. The first mask pattern PM1′ may have fourth openings OP4, which are provided on the connection region CCR to expose the first to third contact holes CTH1, CTH2, and CTH3 that are farther from the cell array region CAR. For example, in FIG. 11, the second three contact holes CTH1, CTH2, and CTH3, which are next to the first three holes CTH1, CTH2, and CTH3, may be considered as being farther from the cell array region CAR, but the disclosure is not limited thereto. Each of the fourth openings OP4 may have a fourth diameter R4 in a horizontal direction. The fourth diameter R4 of the fourth openings OP4 may be substantially equal to the diameters of the first to third contact holes CTH1, CTH2, and CTH3. Although FIG. 11B illustrates an example embodiment in which the first three contact holes CTH1, CTH2, and CTH3 are covered and the next three contact holes CTH1, CTH2, and CTH3 are exposed, the disclosure is not limited thereto. As such, according to another embodiment, the one or more of the closer contact holes may be exposed by first mask pattern PM1′ and/or one or more of the farther holes may be covered by the first mask pattern PM1′.

After the formation of the first mask pattern PM1′, a spacer insulating layer SDL may be formed on the first mask pattern PM1′. The spacer insulating layer SDL may be provided on a top surface of the first mask pattern PM1′. For example, the spacer insulating layer SDL may cover a top surface of the first mask pattern PM1′. The spacer insulating layer SDL may be formed to have a uniform thickness. For example, the spacer insulating layer SDL may be formed by an atomic layer deposition process or a chemical vapor deposition process.

The spacer insulating layer SDL may be extended from a region on the top surface of the first mask pattern PM1′ into the fourth openings OP4 of the first mask pattern PM1′. The spacer insulating layer SDL may be provided on the inner side surface of the fourth openings OP4. The spacer insulating layer SDL may cover the inner side surface of the fourth openings OP4. In addition, the spacer insulating layer SDL may be extended into the first to third contact holes CTH1, CTH2, and CTH3 of the mold structure MS exposed by the fourth openings OP4. The spacer insulating layer SDL may be provided on the inner side surfaces and bottom surfaces of the first to third contact holes CTH1, CTH2, and CTH3. For example, the spacer insulating layer SDL may cover the inner side surfaces and bottom surfaces of the first to third contact holes CTH1, CTH2, and CTH3.

Thereafter, a second mask pattern PM2 may be formed on the spacer insulating layer SDL. The formation of the second mask pattern PM2 may include forming a second photoresist layer, performing a bake process on the second photoresist layer, and performing an exposure process using a second photomask MK2. Thus, the second mask pattern PM2 may be formed from the second photoresist layer. For example, the formation of the second mask pattern PM2 may be substantially the same as the process of forming the first mask pattern PM1′.

The second mask pattern PM2 may have fifth openings OP5 on the connection region CCR. Each of the fifth openings OP5 may be vertically overlapped with each of the fourth openings OP4. Thus, the first to third contact holes CTH1, CTH2, and CTH3 may be exposed through the fourth and fifth openings OP4 and OP5. Each of the fifth openings OP5 may have a fifth diameter R5 in a horizontal direction, and the fifth diameter R5 of the fifth openings OP5 may be substantially equal to or larger than the fourth diameter R4 of the fourth openings OP4. In addition, the second mask pattern PM2 may have a second thickness T2 in the third direction D3. For the same reason described above, the second thickness T2 of the second mask pattern PM2 may be substantially equal to the first thickness T1 of the first mask pattern PM1′. For example, the second thickness T2 of the second mask pattern PM2 may range from about 2 μm to about 3 μm.

In the step of forming the second mask pattern PM2, the second photoresist layer may be spaced apart from the first mask pattern PM1′ by the spacer insulating layer SDL. Thus, the second photoresist layer may not react with the first mask pattern PM1′. Accordingly, it may be possible to prevent the second photoresist layer from swelling into the fourth openings OP4 of the first mask pattern PM1′ and from closing the fourth openings OP4.

That is, the spacer insulating layer SDL may be provided between the first and second mask patterns PM1′ and PM2 to be in contact with them, and thus, it may be possible to prevent the first and second mask patterns PM1′ and PM2 from being in contact with each other. That is, the spacer insulating layer SDL may serve as a barrier layer. The spacer insulating layer SDL may be effectively used as the barrier layer, in an example case in which the spacer insulating layer SDL has a large thickness. For example, in an example case in which the spacer insulating layer SDL has a large thickness greater than a reference value, the spacer insulating layer SDL may be effectively used as the barrier layer. However, if the spacer insulating layer SDL has an excessively large thickness, the fourth openings OP4 and the first to third contact holes CTH1, CTH2, and CTH3 may be closed by the spacer insulating layer SDL. This means that it is necessary to form the spacer insulating layer SDL within an appropriate thickness range. For example, the thickness of the spacer insulating layer SDL may range from about 0.01 to about 0.05 of a diameter of each of the first to third contact holes CTH1, CTH2, and CTH3. The thickness of the spacer insulating layer SDL may range from about 4 nm to about 25 nm.

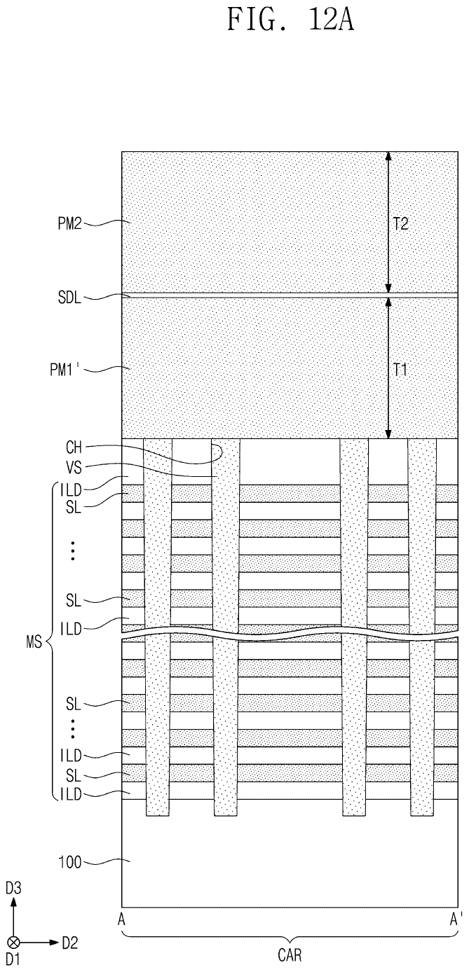

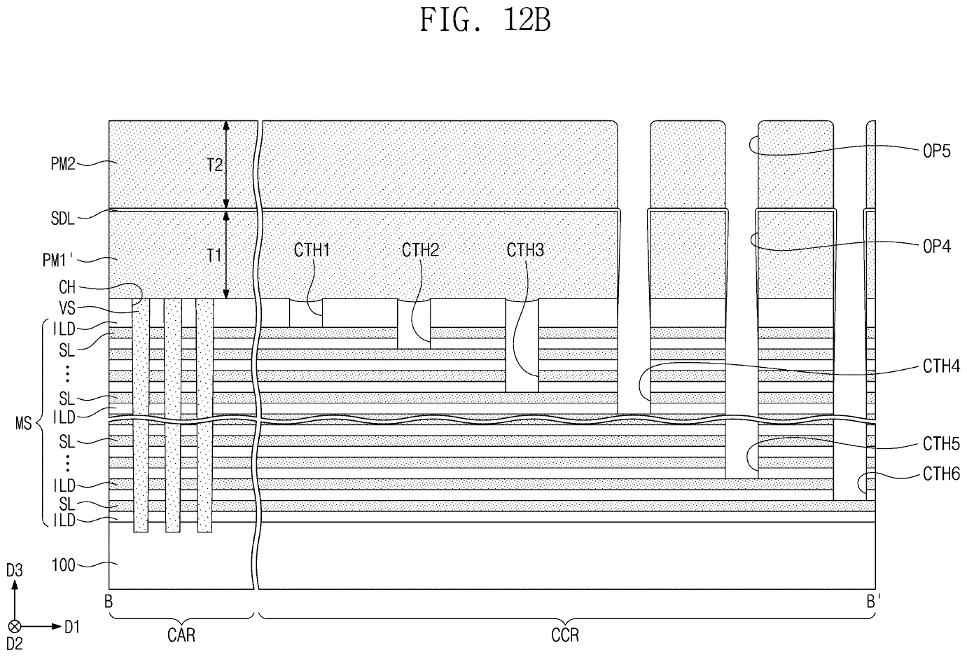

Referring to FIGS. 12A and 12B, a second etching process may be performed using the first and second mask patterns PM1′ and PM2 as an etch mask. For example, the second etching process may be an anisotropic etching process, similar to the first etching process. During the second etching process, the first to third contact holes CTH1, CTH2, and CTH3 of the mold structure MS exposed by the fourth and fifth openings OP4 and OP5 may be additionally etched to form fourth contact hole CTH4, a fifth contact hole CTH5 and a sixth contact hole CTH6.

For example, the fourth contact hole CTH4 may be formed from the first contact hole CTH1, the fifth contact hole CTH5 may be formed from the second contact hole CTH2, and the sixth contact hole CTH6 may be formed from the third contact hole CTH3. Since the first to third contact holes CTH1, CTH2, and CTH3 have different depths from each other, the fourth to sixth contact holes CTH4, CTH5, and CTH6, which are formed from the first to third contact holes CTH1, CTH2, and CTH3, may have different depths from each other. Thus, the first to sixth contact holes CTH1, CTH2, CTH3, CTH4, CTH5, and CTH6 may be formed to have different vertical depths in the third direction D3.

In the second etching process, the spacer insulating layer SDL may serve as a spacer layer protecting the fourth openings OP4 of the first mask pattern PM1′ and the inner side surfaces of the fourth to sixth contact holes CTH4, CTH5, and CTH6 of the mold structure MS. Thus, the spacer insulating layer SDL may be partially removed during the process of forming the fourth to sixth contact holes CTH4, CTH5, and CTH6. For example, the spacer insulating layer SDL provided on the inner side surfaces of the fourth openings OP4 and the inner side surfaces and bottom surfaces of the fourth to sixth contact holes CTH4, CTH5, and CTH6 may be removed. For example, the spacer insulating layer SDL covering the inner side surfaces of the fourth openings OP4 and the inner side surfaces and bottom surfaces of the fourth to sixth contact holes CTH4, CTH5, and CTH6 may be removed by the second etching process. Thus, it may be possible to prevent a bowing phenomenon, which may occur in the first mask pattern PM1′ or the fourth to sixth contact holes CTH4, CTH5, and CTH6, and thus, to form the fourth to sixth contact holes CTH4, CTH5, and CTH6 with a uniform diameter.

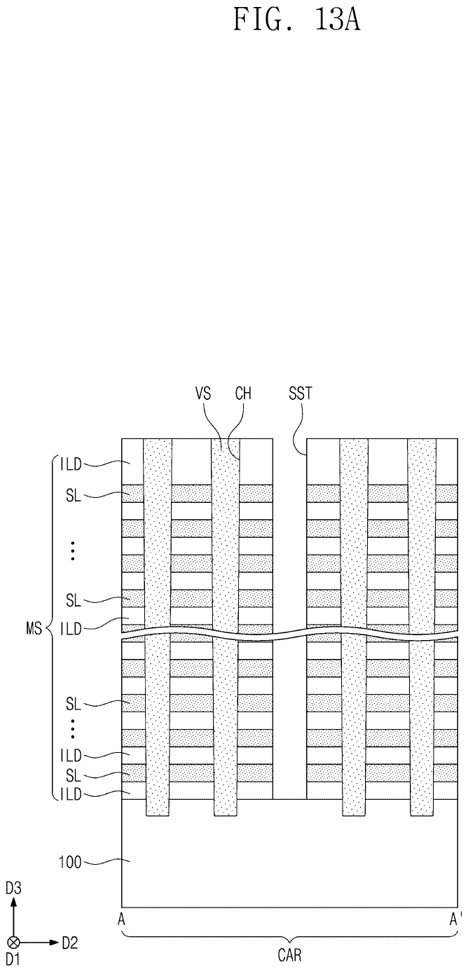

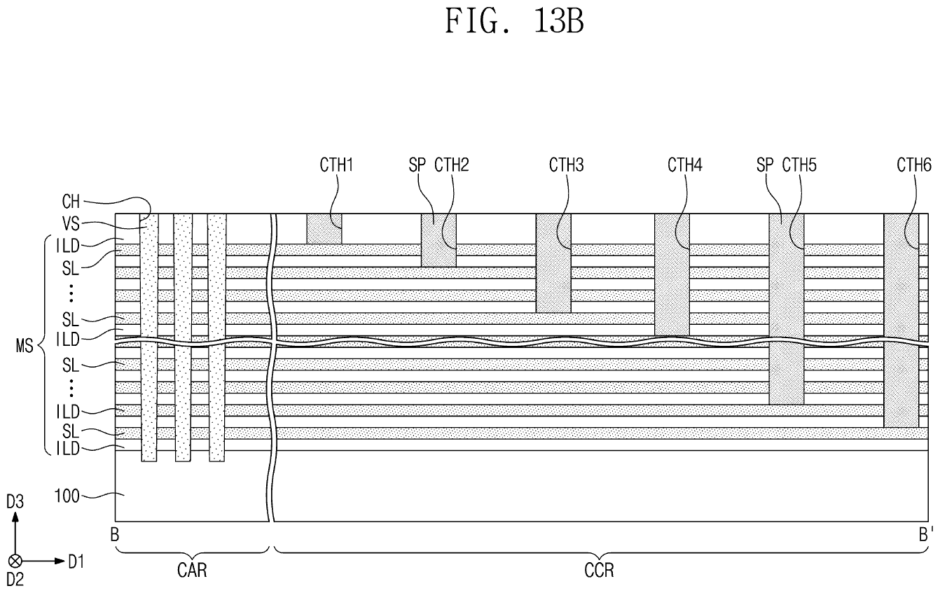

Referring to FIGS. 13A and 13B, the first and second mask patterns PM1′ and PM2 may be removed. The spacer insulating layer SDL may also be removed during the process of removing the first and second mask patterns PM1′ and PM2. However, the disclosure is not limited to this example, a portion of the spacer insulating layer SDL may be left.

Sacrificial patterns SP may be formed on the connection region CCR. Each of the sacrificial patterns SP may fill each of the first to sixth contact holes CTH1, CTH2, CTH3, CTH4, CTH5, and CTH6 of the mold structure MS. Thus, the sacrificial patterns SP may have different lengths from each other in the third direction D3. The sacrificial patterns SP may include a material having an etch selectivity with respect to the interlayer insulating layers ILD and the sacrificial layers SL. For example, the sacrificial patterns SP may be formed of or include polysilicon.

In an embodiment, before the formation of the sacrificial patterns SP, a protection insulating layer may be further formed in the first to sixth contact holes CTH1, CTH2, CTH3, CTH4, CTH5, and CTH6. The protection insulating layer may be provided on the inner side surfaces of the first to sixth contact holes CTH1, CTH2, CTH3, CTH4, CTH5, and CTH6. The protection insulating layer may cover the inner side surfaces of the first to sixth contact holes CTH1, CTH2, CTH3, CTH4, CTH5, and CTH6 with a uniform thickness. The protection insulating layer may be used to protect the sacrificial patterns SP in a subsequent process of removing the sacrificial layers SL.

Thereafter, a separation trench SST may be formed to penetrate the mold structure MS in the third direction D3. The separation trench SST may be extended in the first direction D1, on the cell array region CAR and the connection region CCR. The sacrificial layers SL and the interlayer insulating layers ILD of the mold structure MS may be partially exposed by the separation trench SST.

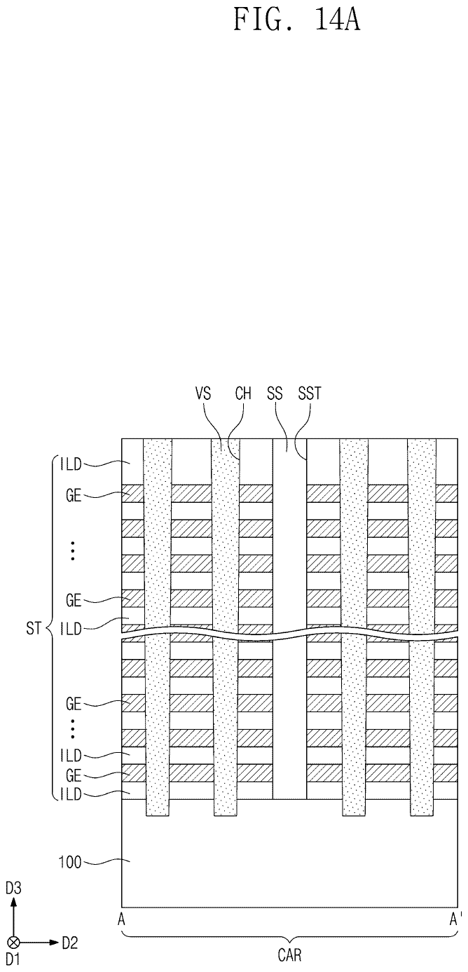

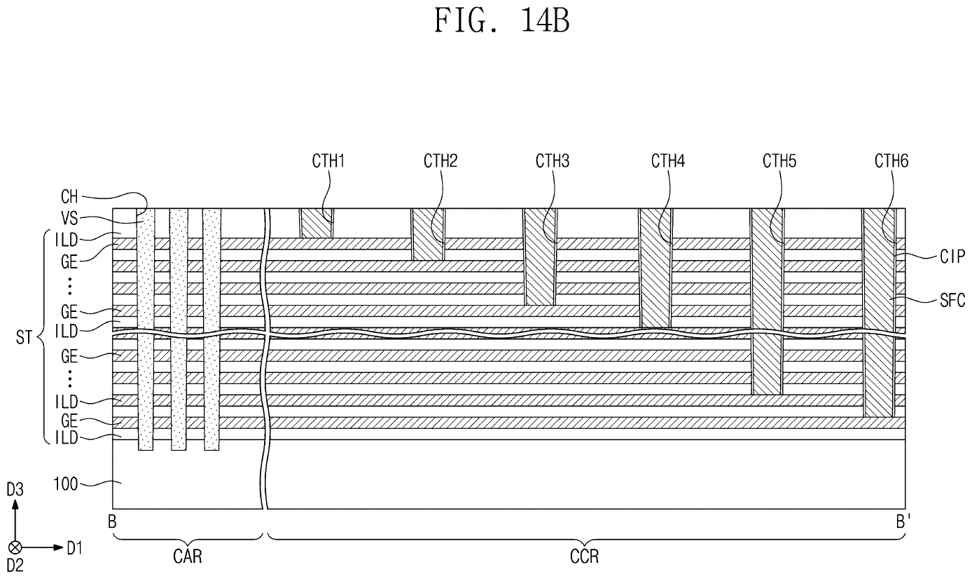

Referring to FIGS. 14A and 14B, the stack ST may be formed. The formation of the stack ST may include selectively removing the sacrificial layers SL exposed by the separation trench SST. The selective removal of the sacrificial layers SL may be performed through a wet etching process using etching solution with an etch selectivity. Since only the sacrificial layers SL are removed, the interlayer insulating layers ILD and the sacrificial patterns SP may remain intact.

Due to the selective removal of the sacrificial layers SL, the mold structure MS may be structurally weakened. For example, the mold structure MS may collapse or tilt. In this case, the vertical structures VS, the dummy vertical structures DVS, and the sacrificial patterns SP may support the mold structure MS.

The gate electrodes GE may be formed in a space, from which the sacrificial layers SL is removed. The gate electrodes GE may fill a space, from which the sacrificial layers SL is removed. For example, the formation of the gate electrodes GE may include sequentially depositing a metal nitride layer (e.g., TiN, TaN, or WN) and a metal layer (e.g., W, Al, Ti, Ta, Co, or Cu). Thus, the stack ST, in which the gate electrodes GE and the interlayer insulating layers ILD are alternately stacked, may be formed on the carrier substrate 100.

The gate electrodes GE may be formed, and a separation structure SS may be formed in the separation trench SST. The separation structure SS may include a single-or multi-layered structure including at least one of insulating materials.

After the formation of the stack ST, the sacrificial patterns SP may be removed. Since the sacrificial patterns SP have an etch selectivity with respect to the gate electrodes GE and the interlayer insulating layers ILD of the stack ST, the sacrificial patterns SP may be selectively removed. During the removal of the sacrificial patterns SP, the stack ST may not be removed. Since the sacrificial patterns SP are removed, the first to sixth contact holes CTH1, CTH2, CTH3, CTH4, CTH5, and CTH6 may be exposed again.

Thereafter, the contact insulating patterns CIP may be provided on the inner side surfaces of the first to sixth contact holes CTH1, CTH2, CTH3, CTH4, CTH5, and CTH6. For example, the contact insulating patterns CIP may be formed to cover the inner side surfaces of the first to sixth contact holes CTH1, CTH2, CTH3, CTH4, CTH5, and CTH6. The contact insulating patterns CIP may be formed by forming an insulating layer to cover the first to sixth contact holes CTH1, CTH2, CTH3, CTH4, CTH5, and CTH6 with a uniform thickness and performing an etch-back process. The etch-back process may be performed to expose the bottom surfaces of the first to sixth contact holes CTH1, CTH2, CTH3, CTH4, CTH5, and CTH6 again.

After the formation of the contact insulating patterns CIP, the electrode contacts SFC may be formed to fill the first to sixth contact holes CTH1, CTH2, CTH3, CTH4, CTH5, and CTH6. The formation of the electrode contacts SFC may include filling the first to sixth contact holes CTH1, CTH2, CTH3, CTH4, CTH5, and CTH6 with a metallic material and performing a planarization process on the metallic material.

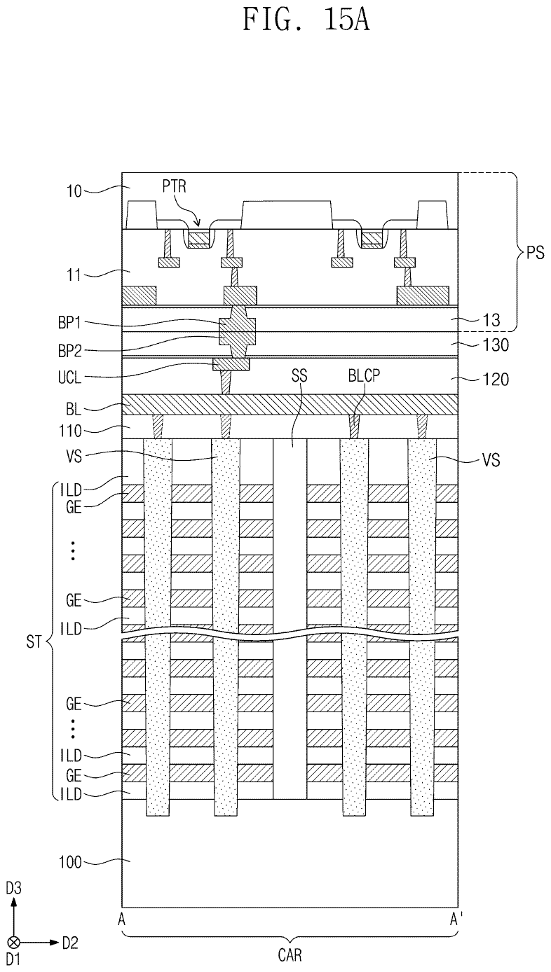

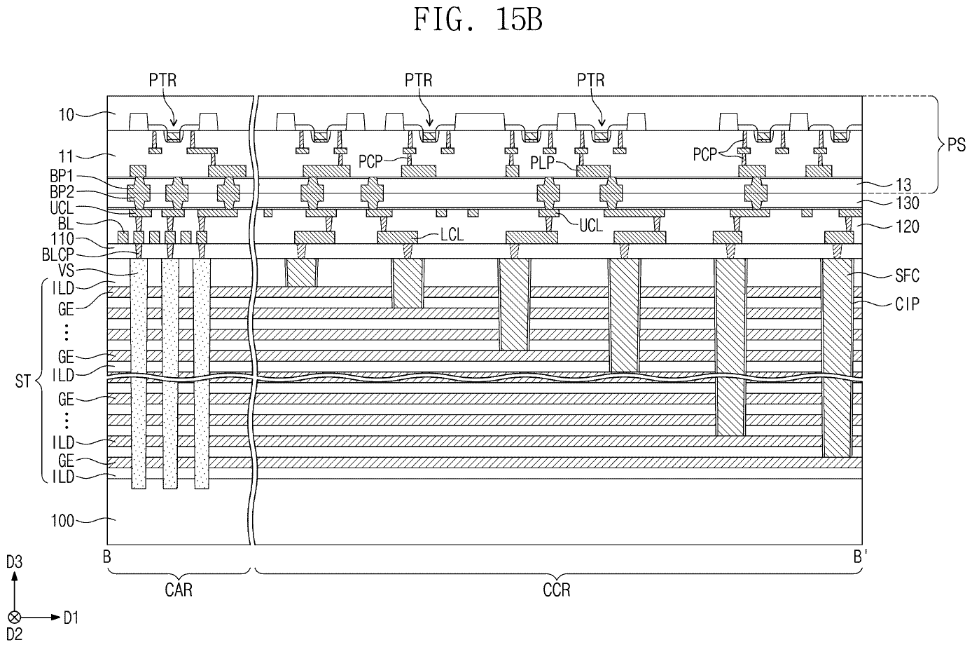

Referring to FIGS. 15A and 15B, the first to third interlayer insulating layers 110, 120, and 130 may be sequentially formed on the stack ST. The bit line plugs BLCP and the conductive line plugs CLCP, which are connected to the vertical structures VS and the electrode contacts SFC, respectively, may be formed in the first interlayer insulating layer 110.

The bit lines BL, the lower conductive lines LCL, and the upper conductive lines UCL may be formed in the second interlayer insulating layer 120. The formation of the bit lines BL, the lower conductive lines LCL, and the upper conductive lines UCL may include patterning the second interlayer insulating layer 120 and filling the patterned region of the second interlayer insulating layer 120 with a conductive material. The bit lines BL may be connected to the bit line plugs BLCP, and the lower conductive lines LCL may be connected to the conductive line plugs CLCP.

The second bonding pads BP2 may be formed in the third interlayer insulating layer 130. The formation of the second bonding pads BP2 may include performing a planarization process on the third interlayer insulating layer 130. Thus, surfaces of the second bonding pads BP2 may be exposed to the outside. The second bonding pads BP2 may be connected to the upper conductive lines UCL.

Thereafter, the peripheral circuit structure PS may be formed. The formation of the peripheral circuit structure PS may include forming the peripheral transistors PTR on the active region of the substrate 10, forming the peripheral plugs PCP and the peripheral circuit lines PLP, which are electrically connected to the peripheral transistors PTR, forming the first lower insulating layer 11 on the peripheral transistors PTR, the peripheral plugs PCP, and the peripheral circuit lines PLP, forming the first bonding pads BP1 connected to the peripheral circuit lines PLP, and forming the second lower insulating layer 13 to enclose the first bonding pads BP1. For example, the first lower insulating layer 11 may be provided to cover the peripheral transistors PTR, the peripheral plugs PCP, and the peripheral circuit lines PLP.

The peripheral circuit structure PS may be bonded to the third interlayer insulating layer 130. More specifically, the first bonding pads BP1 of the peripheral circuit structure PS and the second bonding pads BP2 in the third interlayer insulating layer 130 may be bonded to each other to be in contact with each other.

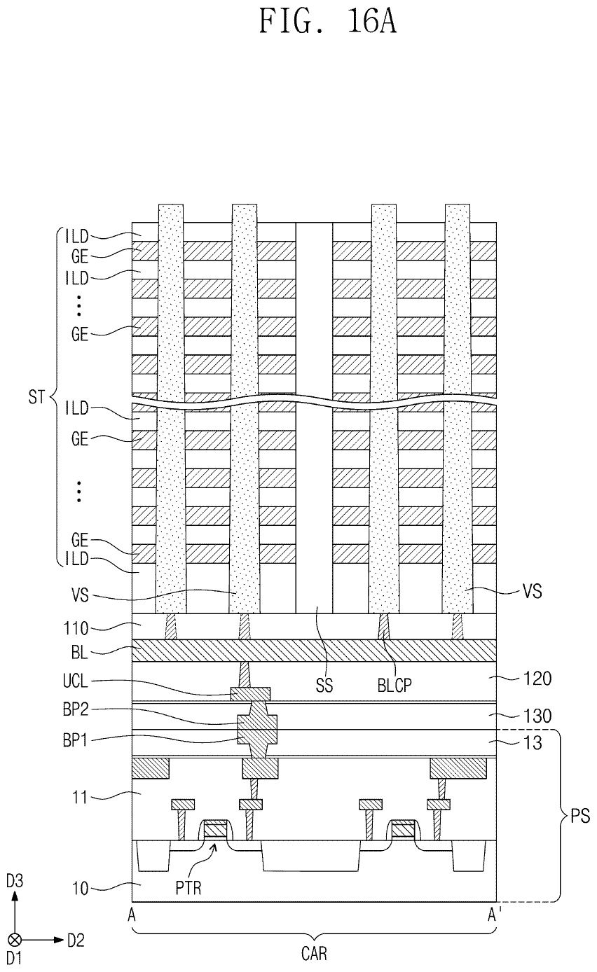

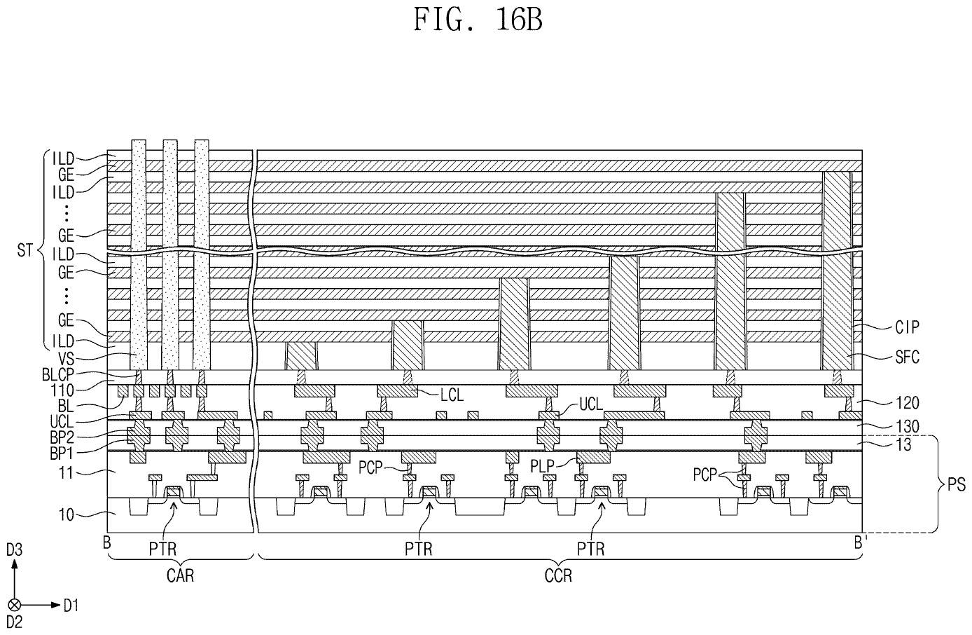

Referring to FIGS. 16A and 16B, the carrier substrate 100 may be inverted. Thus, the peripheral circuit structure PS may be placed below the stack ST. Thereafter, the carrier substrate 100 may be removed. The removal of the carrier substrate 100 may include one of a grinding process, a planarization process, and an etching process. Since the carrier substrate 100 is removed, the vertical structures VS may be partially exposed.

After the removal of the carrier substrate 100, the data storage pattern DSP of each of the vertical structures VS may be partially removed, as described with reference to FIG. 7. Thus, the vertical semiconductor pattern VP of each of the vertical structures VS may be exposed.

Referring back to FIGS. 6A and 6B, the source structure CST may be formed on the cell array region CAR. The source structure CST may be provided on the exposed portions of the vertical structures VS. For example, the source structure CST may cover the exposed portions of the vertical structures VS. Thereafter, Thereafter, the first upper insulating layer UIL1 may be provided on the source structure CST and the stack ST. For example, the first upper insulating layer UIL1 may be formed to cover the source structure CST and the stack ST.

Thereafter, the second upper insulating layer UIL2, the protection layer PTL, and the passivation layer PAS may be sequentially formed on the first upper insulating layer UIL1.

In a method of fabricating a three-dimensional semiconductor device according to an embodiment of the disclosure, contact holes may be formed using a plurality of mask patterns, which are stacked in a vertical direction, and the spacer insulating layer SDL therebetween. Since openings in each of the mask patterns are vertically overlapped with each other, the mask patterns may serve as a single mask pattern. Thus, it may be possible to easily form contact holes with a high aspect ratio.

The spacer insulating layer SDL may be used as a barrier layer, which prevents the mask patterns from being in contact with each other and reacting with each other, in a step of forming the mask patterns. Thus, it may be possible to prevent the openings of the mask patterns from closing.

In addition, the spacer insulating layer SDL may also be used as a spacer layer in an etching process of forming the contact holes, and a bowing phenomenon by the etching process may be prevented. Thus, the contact holes may be formed to have a uniform diameter, and adjacent ones of the contact holes may be spaced apart from each other by a sufficiently large distance.

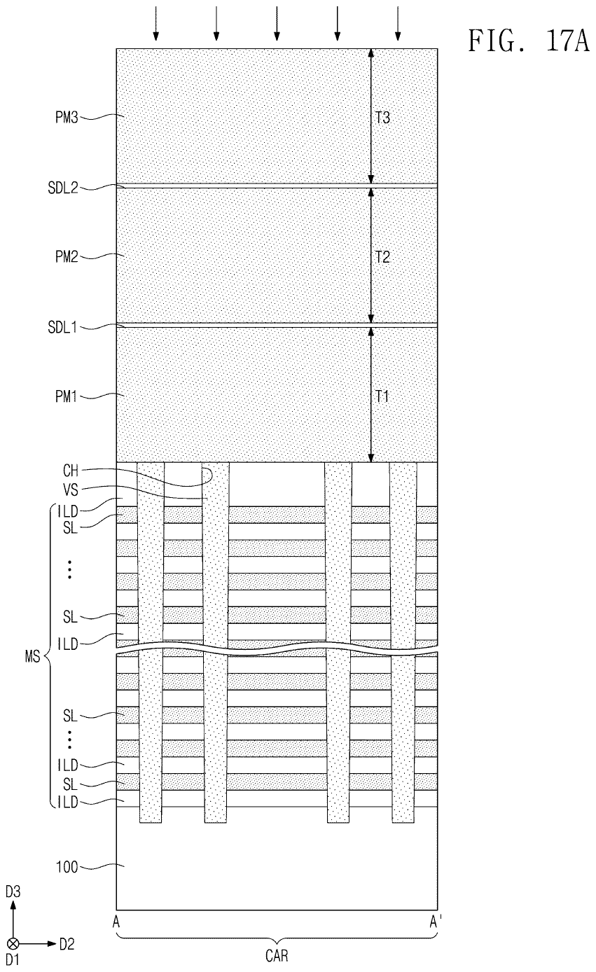

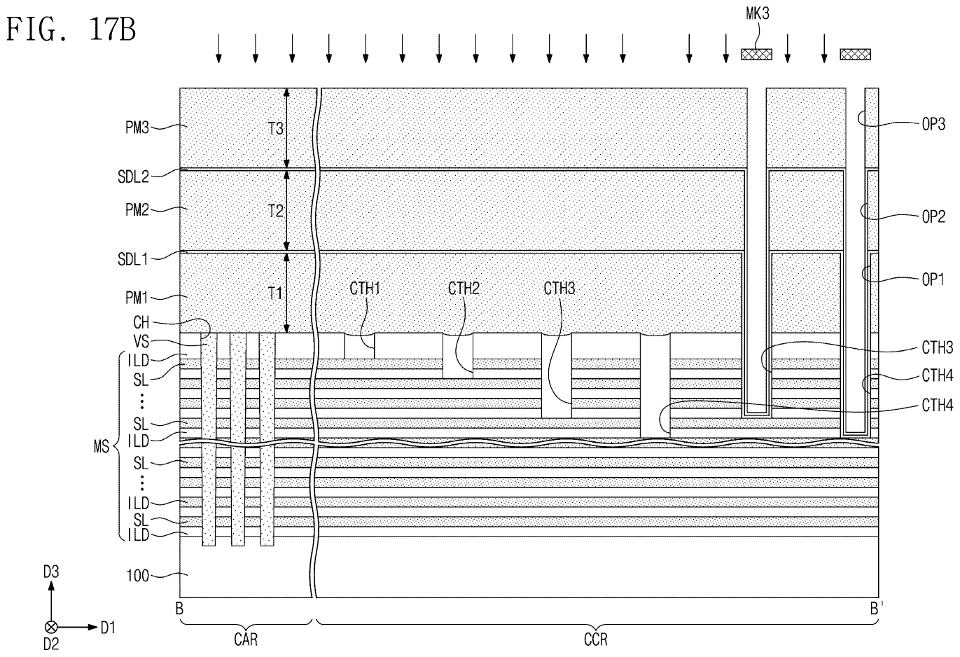

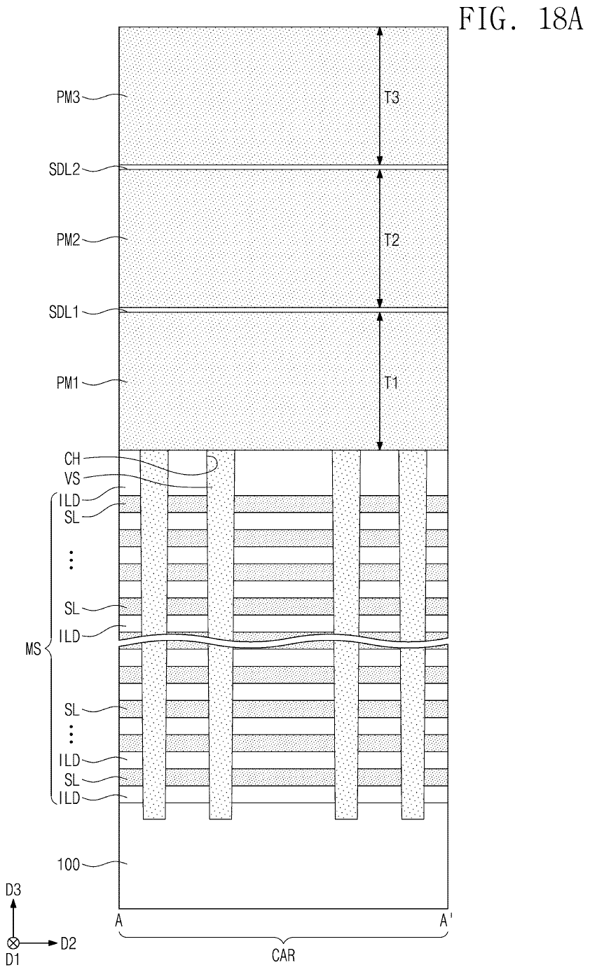

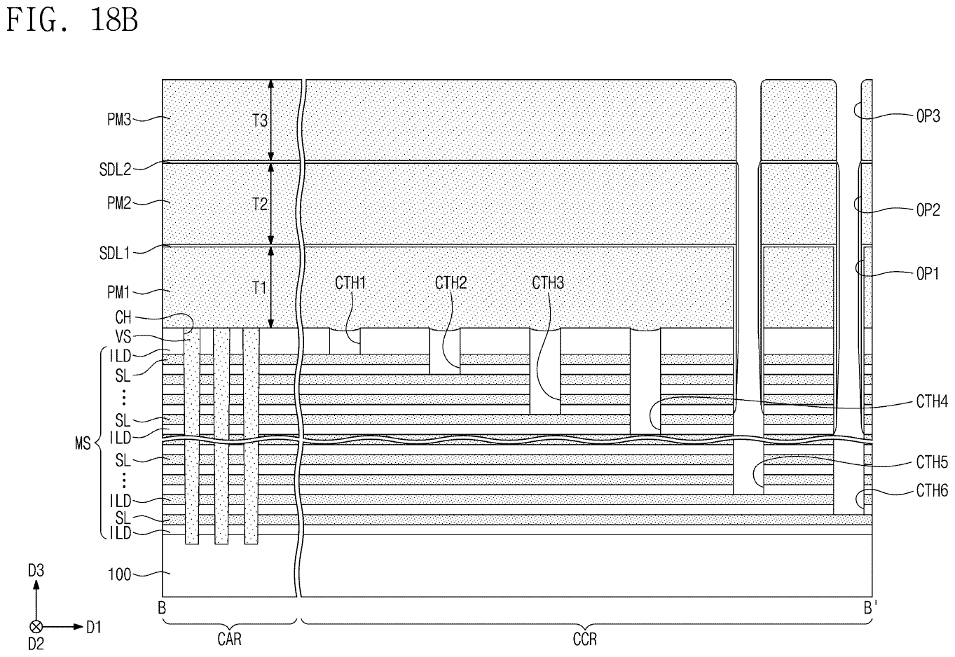

FIGS. 17A, 17B, 18A, and 18B are diagrams illustrating a method of fabricating a three-dimensional semiconductor device, according to an embodiment of the disclosure. FIG. 17A and 18A are sectional views taken along the line A-A′ of FIG. 5. FIG. 17B, and 18B are sectional views taken along the line B-B′ of FIG. 5.

Referring to FIGS. 17A and 17B, the mold structure MS may be formed to include the interlayer insulating layers ILD and the sacrificial layers SL, which are alternately stacked on the carrier substrate 100. The vertical structures VS may be formed on the cell array region CAR to penetrate the mold structure MS. The formation of the mold structure MS and the vertical structures VS may be substantially the same as that described with reference to FIGS. 8A to 9B.

According to an embodiment, the first to fourth contact holes CTH1, CTH2, CTH3, and CTH4 may be formed on the connection region CCR to penetrate the mold structure MS. For example, the first to fourth contact holes CTH1, CTH2, CTH3, and CTH4 may have vertical depths that are different from each other in the third direction D3. The formation of the first to fourth contact holes CTH1, CTH2, CTH3, and CTH4 may be substantially the same as that described with reference to FIGS. 9A to 12B, but the disclosure is not limited to this example.

Thereafter, the first mask pattern PM1, a first spacer insulating layer SDL1, the second mask pattern PM2, a second spacer insulating layer SDL2, and a third mask pattern PM3 may be sequentially formed on the mold structure MS. The first spacer insulating layer SDL1 may be placed between the first mask pattern PM1 and the second mask pattern PM2 and may be in contact with them. The second spacer insulating layer SDL2 may be placed between the second and third mask patterns PM2 and PM3 and may be in contact with them.

The formation of the first mask pattern PM1 may include forming a first photoresist layer, performing a bake process on the first photoresist layer, and performing an exposure process using a third photomask MK3. Thus, the first mask pattern PM1 may be formed from the first photoresist layer. The formation of the second and third mask patterns PM2 and PM3 may be substantially the same as the formation of the first mask pattern PM1. For example, the formation of each of the first to third mask patterns PM1, PM2, and PM3 may be substantially the same as that described with reference to FIGS. 9A and 9B.

The first to third mask patterns PM1, PM2, and PM3 may have the first to third openings OP1, OP2, and OP3, respectively, which are formed to expose the third and fourth contact holes CTH3 and CTH4 that are far from the cell array region CAR. For example, the first openings OP1 of the first mask pattern PM1, the second openings OP2 of the second mask pattern PM2, and the third openings OP3 of the third mask pattern PM3 may be provided on the connection region CCR. In addition, the first to third openings OP1, OP2, and OP3 of the first to third mask patterns PM1, PM2, and PM3 may be vertically overlapped with each other. Thus, the first to third mask patterns PM1, PM2, and PM3 may serve as a single thick mask pattern.

In addition, the first to third mask patterns PM1, PM2, and PM3 may have first to third thicknesses T1, T2, and T3 in the third direction D3. The first thickness T1 of the first mask pattern PM1, the second thickness T2 of the second mask pattern PM2, and the third thickness T3 of the third mask pattern PM3 may be substantially equal to each other, but the disclosure is not limited to this example. For example, each of the first to third thicknesses T1, T2, and T3 of the first to third mask patterns PM1, PM2, and PM3 may range from about 2 μm to about 3 μm.

After the formation of the first mask pattern PM1 and before the formation of the second mask pattern PM2, the first spacer insulating layer SDL1 may be provided on the first mask pattern PM1. For example, the first spacer insulating layer SDL1 may be formed to cover the first mask pattern PM1. The first spacer insulating layer SDL1 may be extended from a top surface of the first mask pattern PM1 into the first openings OP1 of the first mask pattern PM1. For example, the first spacer insulating layer SDL1 may cover inner side surfaces of the first openings OP1 of the first mask pattern PM1 and inner side surfaces and bottom surfaces of the third and fourth contact holes CTH3 and CTH4 of the mold structure MS.

After the formation of the second mask pattern PM2 and before the formation of the third mask pattern PM3, the second spacer insulating layer SDL2 may be provided on the second mask pattern PM2. For example, the second spacer insulating layer SDL2 may be formed to cover the second mask pattern PM2. The second spacer insulating layer SDL2 may be extended from a top surface of the second mask pattern PM2 into the second openings OP2 of the second mask pattern PM2. For example, the second spacer insulating layer SDL2 may be extended to a region on the first spacer insulating layer SDL1 to cover the first spacer insulating layer SDL1. In the case where the first and second spacer insulating layers SDL1 and SDL2 include the same material, an interface between the first and second spacer insulating layers SDL1 and SDL2 may not be visible or observable.

Referring to FIGS. 18A and 18B, a third etching process may be performed using the first to third mask patterns PM1, PM2, and PM3 as an etch mask. For example, the third etching process may be an anisotropic etching process. During the third etching process, the third and fourth contact holes CTH3 and CTH4 of the mold structure MS exposed by the first to third openings OP1, OP2, and OP3 may be additionally etched to form the fifth and sixth contact holes CTH5 and CTH6.

For example, the fifth contact hole CTH5 may be formed from the third contact hole CTH3, and the sixth contact hole CTH6 may be formed from the fourth contact hole CTH4. Since the third and fourth contact holes CTH3 and CTH4 have different depths from each other, the fifth and sixth contact holes CTH5 and CTH6, which are formed from the third and fourth contact holes CTH3 and CTH4, may have different depths from each other. Thus, the first to sixth contact holes CTH1, CTH2, CTH3, CTH4, CTH5, and CTH6 may be formed to have different vertical depths in the third direction D3.

In the third etching process, the first and second spacer insulating layers SDL1 and SDL2 may serve as a spacer layer protecting inner side surfaces of the first and second openings OP1 and OP2 of the first and second mask patterns PM1 and PM2 and the fifth and sixth contact holes CTH5 and CTH6 of the mold structure MS. The first and second spacer insulating layers SDL1 and SDL2 may be partially removed during the formation of the fifth and sixth contact holes CTH5 and CTH6. For example, the first and second spacer insulating layers SDL1 and SDL2 provided on the inner side surfaces and bottom surfaces of the fifth and sixth contact holes CTH5 and CTH6 may be removed. For example, the first and second spacer insulating layers SDL1 and SDL2 covering the inner side surfaces and bottom surfaces of the fifth and sixth contact holes CTH5 and CTH6 may be removed by the third etching process. Thus, it may be possible to prevent a bowing phenomenon from occurring in the first mask pattern PM1 or the fifth and sixth contact holes CTH5 and CTH6 and to form the fifth and sixth contact holes CTH5 and CTH6 with a uniform diameter.

Thereafter, the stack ST, the electrode contacts SFC, and the peripheral circuit structure PS may be formed, as described with reference to FIGS. 13A to 16B.

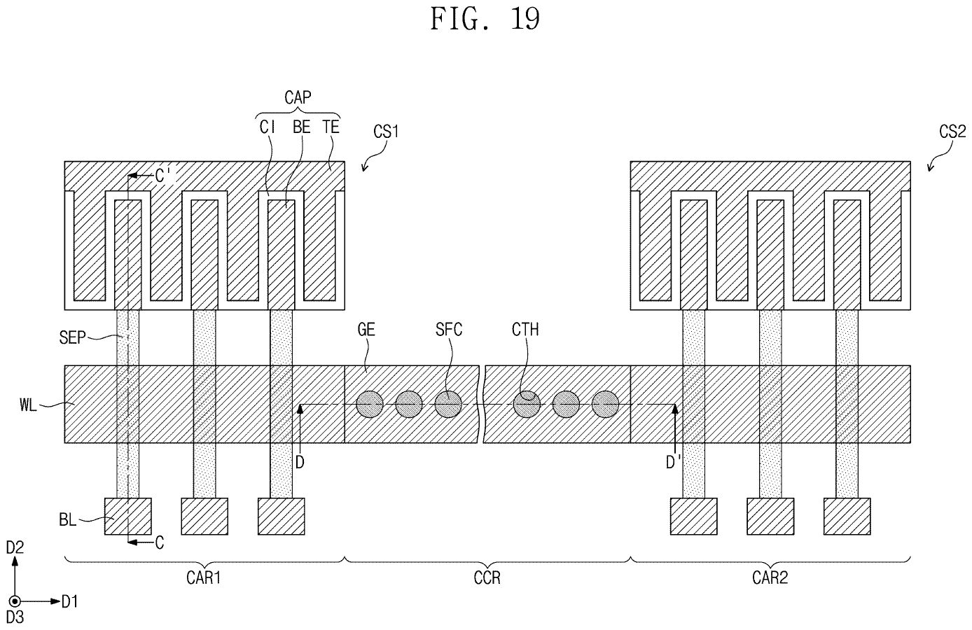

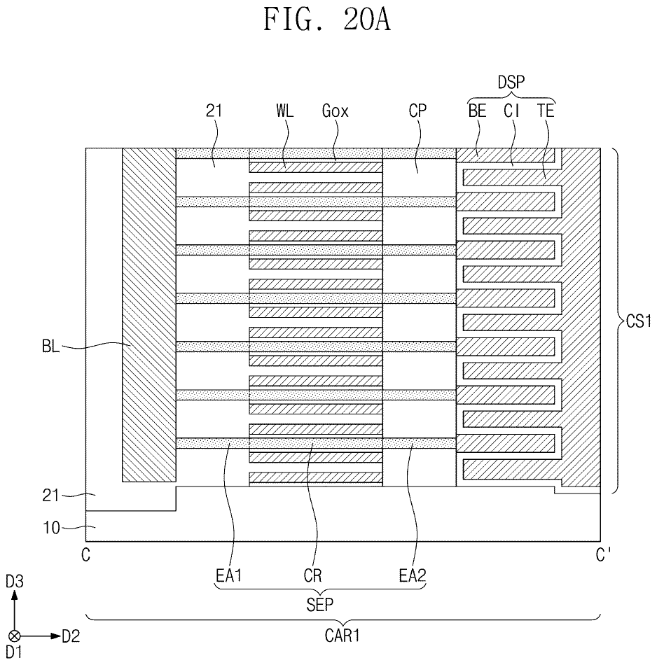

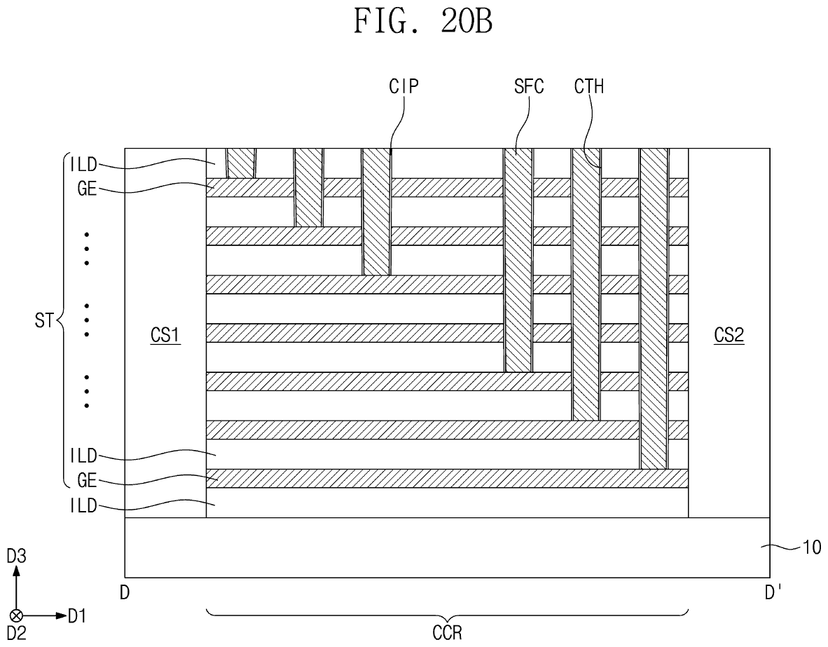

FIG. 19 is a plan view illustrating a three-dimensional semiconductor device according to an embodiment of the disclosure. FIGS. 20A and 20B are sectional views, which are taken alone lines C-C′ and D-D′ of FIG. 19 to illustrate a three-dimensional semiconductor device according to an embodiment of the disclosure.

Referring to FIGS. 19, 20A, and 20B, a three-dimensional semiconductor device may include a stack ST on a substrate 10 and first and second cell array structures CS1 and CS2 on both sides of the stack ST. Each of the first and second cell array structures CS1 and CS2 may include capacitors CAP, which are vertically overlapped with each other. For example, a three-dimensional semiconductor device according to an embodiment of the disclosure may be a Vertical Stacked DRAM (VSDRAM).

The substrate 10 may include cell array regions and a connection region CCR. The cell array regions may include a first cell array region CAR1 and a second cell array region CAR2, which are spaced apart from each other in the first direction D1 with the connection region CCR interposed therebetween. The first cell array structure CS1 may be placed on the first cell array region CAR1, and the second cell array structure CS2 may be placed on the second cell array region CAR2.

The first cell array structure CS1 may include semiconductor patterns SEP, which are spaced apart from each other in the third direction D3, bit lines BL, each of which is placed on first edge portions EA1 of the semiconductor patterns SEP and is extended in the third direction D3, word lines WL, which are extended in the first direction D1 to surround the channel regions CR of the semiconductor patterns SEP, and capacitors CAP, which are placed on second edge portions EA2 of the semiconductor patterns SEP and are extended in the third direction D3. The capacitors CAP may include bottom electrodes BE, a top electrode TE, and a capacitor dielectric layer CI between the bottom electrodes BE and the top electrode TE.

In addition, the first cell array structure CS1 may include gate dielectric layers Gox between the word lines WL and the semiconductor patterns SEP, capping patterns CP between the capacitors CAP and the word lines WL, and an insulating gapfill layer 21 provided on the bit lines BL, the semiconductor patterns SEP, and the word lines WL. an insulating gapfill layer 21 covering the bit lines BL, the semiconductor patterns SEP, and the word lines WL

The second cell array structure CS2 may include elements, which have substantially the same features as those in the first cell array structure CS1. For example, the second cell array structure CS2 may include the semiconductor patterns SEP, the bit lines BL, the word lines WL, and the capacitors CAP.

The stack ST may be provided between the first and second cell array structures CS1 and CS2. The stack ST may be located on the connection region CCR. The stack ST may include gate electrodes GE and interlayer insulating layers ILD, which are alternately stacked in the third direction D3. Each of the gate electrodes GE and the interlayer insulating layers ILD may be extended in the first direction D1. The gate electrodes GE may be connected to the word lines WL of the first and second cell array structures CS1 and CS2.

According to an embodiment, electrode contacts SFC may be provided in the stack ST. The electrode contacts SFC may be placed in contact holes CTH penetrating the stack ST. The contact holes CTH may have different vertical depths from each other in the third direction D3. Thus, the electrode contacts SFC may have different vertical lengths from each other in the third direction D3. The electrode contacts SFC may be connected to correspond ones of the gate electrodes GE of the stack ST. Contact insulating patterns CIP may be further provided between the electrode contacts SFC and the stack ST.

The process of forming the electrode contacts SFC in the stack ST may be substantially the same as that in the previous embodiment described with reference to FIGS. 9A to 14B. For example, the contact holes CTH may be formed by an etching process using a plurality of mask patterns, and a spacer insulating layer may be formed between the mask patterns. Thus, it may be possible to form the contact holes CTH with a uniform diameter while preventing the bowing phenomenon.

In a method of fabricating a three-dimensional semiconductor device according to an embodiment of the disclosure, contact holes may be formed using a plurality of vertically-stacked mask patterns and a spacer insulating layer therebetween. Openings of the mask patterns may be vertically overlapped with each other, and in this case, the mask patterns may serve as a single mask pattern. Thus, it may be possible to easily form contact holes with a high aspect ratio.

The spacer insulating layer may be used as a barrier layer, which prevents the mask patterns from being in contact with each other or reacting with each other, in a step of forming the mask patterns. In addition, the spacer insulating layer may serve as a spacer layer, in an etching process for forming the contact holes, thereby preventing a bowing phenomenon from occurring in the etching process.

While example embodiments of the disclosure have been particularly shown and described, it will be understood by one of ordinary skill in the art that variations in form and detail may be made therein without departing from the spirit and scope of the attached claims.

What is claimed is:

1. A method of fabricating a three-dimensional semiconductor device, comprising:
forming a mold structure on a substrate;
forming a first mask pattern on the mold structure, the first mask pattern having a first opening;
forming a first spacer insulating layer on the first mask pattern; and
forming a second mask pattern on the first spacer insulating layer, the second mask pattern having a second opening overlapping the first opening.

2. The method of claim 1, wherein the first spacer insulating layer contacts the first mask pattern and second mask pattern.

3. The method of claim 1, wherein a diameter of the first opening is equal to or smaller than a diameter of the second opening.

4. The method of claim 1, wherein a thickness of each of the first mask pattern and second mask pattern ranges from 2 μm to 3 μm.

5. The method of claim 1, further comprising:
forming a second spacer insulating layer on the second mask pattern; and
forming a third mask pattern on the second spacer insulating layer, the third mask pattern having a third opening,
wherein the third opening is vertically overlaps the first opening and second opening.

6. The method of claim 1, wherein the first spacer insulating layer is provided on an inner side surface of the first opening of the first mask pattern.

7. The method of claim 1, wherein the mold structure comprises a contact hole therein, and
wherein the first spacer insulating layer extends into the contact hole.

8. The method of claim 7, wherein the first spacer insulating layer is provided on an inner side surface and a bottom surface of the contact hole.

9. The method of claim 7, wherein a thickness of the first spacer insulating layer ranges from 0.01 to 0.05 of a diameter of the contact hole.

10. The method of claim 1, further comprising an etching process using the first mask pattern and second mask pattern,
wherein the etching process is performed to remove a portion of the first spacer insulating layer.

11. A method of fabricating a three-dimensional semiconductor device, comprising:
forming a mold structure on a substrate, the substrate including a cell array region and a connection region;
forming a first mask pattern on the mold structure, the first mask pattern having a first opening;
forming a spacer insulating layer on the first mask pattern;
forming a second mask pattern on the spacer insulating layer, the second mask pattern having a second opening; and
forming a contact hole extended into the mold structure,
wherein the spacer insulating layer is provided on an inner side surface of the first opening.

12. The method of claim 11, wherein the contact hole is formed by an etching process using the first mask pattern and second mask pattern.

13. The method of claim 11, wherein the first opening and second opening are on the connection region, and
wherein the first opening overlaps the second opening.

14. The method of claim 11, further comprising:
forming a plurality of vertical structures on the cell array region to penetrate the mold structure,
wherein each of the plurality of vertical structures comprises a vertical semiconductor pattern, a data storage pattern surrounding the vertical semiconductor pattern, and a gapfill insulating pattern filling the vertical semiconductor pattern.

15. The method of claim 11, further comprising:
forming a capacitor on the cell array region,
wherein the capacitor comprises a bottom electrode, a top electrode, and a capacitor dielectric layer between the bottom electrode and the top electrode.

16. The method of claim 11, wherein the forming of the contact hole comprises forming a plurality of contact holes, and
wherein the plurality of contact holes have different vertical lengths from each other.

17. The method of claim 11, wherein a diameter of the contact hole ranges from nm to 500 nm, and
wherein a thickness of the spacer insulating layer ranges from 0.01 to 0.05 of the diameter of the contact hole.

18. A method of fabricating a three-dimensional semiconductor device, comprising:
forming a mold structure including a plurality of interlayer insulating layers and a plurality of sacrificial layers that are alternatingly stacked on a substrate, the substrate including a cell array region and a connection region;
forming a plurality of vertical structures on the cell array region to penetrate the mold structure;
forming a first mask pattern on the mold structure the first mask pattern having a first opening;
forming a spacer insulating layer on the first mask pattern;
forming a second mask pattern on the spacer insulating layer, the second mask pattern having a second opening;
performing an etching process using the first mask pattern and second mask pattern to form a contact hole extended into the mold structure;
forming an electrode contact in the contact hole; and
removing the plurality of sacrificial layers of the mold structure to form a plurality of gate electrodes,
wherein the first opening overlaps the second opening on the connection region.

19. The method of claim 18, wherein the spacer insulating layer extends from a region between the first mask pattern and second mask pattern to an inner side surface of the first opening, and
wherein the etching process is performed to remove a portion of the spacer insulating layer.

20. The method of claim 18, wherein the first mask pattern and second mask pattern are spaced apart from each other by the spacer insulating layer.
